(19) United States
(12) Patent Application Publication
(10) Pub. No.: US 2026/0099021 A1
(43) Pub. Date: Apr. 9, 2026

(54) WIRE-FREE OPTICAL SENSOR PACKAGE WITH AN INORGANIC SUBSTRATE

(71) Applicant: SEMICONDUCTOR COMPONENTS INDUSTRIES, LLC, Scottsdale, AZ (US)

(72) Inventors: Swarnal BORTHAKUR, Boise, ID (US); Christopher D. SILSBY, Corvallis, OR (US)

(73) Assignee: SEMICONDUCTOR COMPONENTS INDUSTRIES, LLC, Scottsdale, AZ (US)

(21) Appl. No.: 18/905,671

(22) Filed: Oct. 3, 2024

(51) Int. Cl. G02B 6/42; H01L 23/00; H01L 23/31; H01L 23/498; H01L 25/16

(52) U.S. Cl. CPC G02B 6/4283; H10W 70/635; H10W 74/117; H10W 90/00; H10W 90/701; H10W 90/794

(57) ABSTRACT

A package includes an inorganic substrate with a first inter-metal dielectric layer disposed on a first surface of the inorganic substrate. An optical sensor die is attached to and electrically connected to a pad in the first inter-metal dielectric layer by a connector. A molding material layer is disposed on the first inter-metal dielectric layer encapsulating the optical sensor die. A second inter-metal dielectric layer is disposed on the molding material layer. An opening extends through the molding material layer between the first inter-metal dielectric layer and the second inter-metal dielectric layer. The opening is filled or lined with conductive material electrically connecting the first inter-metal dielectric layer and the second inter-metal dielectric layer.

### TECHNICAL FIELD

This description relates to packaging of semiconductor optical sensors.

### BACKGROUND

A semiconductor optical sensor is configured to convert a radiation intensity and a wavelength spectrum into electrical signals. The semiconductor optical sensor can be mounted on a ceramic substrate and packaged, for example, as a CLCC (Ceramic Leadless Chip Carrier) package. Smaller form factor optical sensors, which are in demand for mobile phone, cameras and automotive applications, can, for example, use Imaging Ball Grid Array (iBGA) packaging. The iBGA packages use organic or plastic substrates (e.g., a bismaleimide triazine (BT) substrate) instead of the ceramic substrate used, for example, in a CLCC package. Large format industrial sensor packages predominantly use CPGA (ceramic pin grid array) packaging, which are high-cost packages. Similarly, ceramic BGA packages are also higher cost than plastic BGA packages. A lower cost large format sensor would be desirable for many applications including, for example, automotive applications.

### SUMMARY

In an aspect, a package includes an inorganic substrate with a first inter-metal dielectric layer disposed on a first surface of the inorganic substrate. An optical sensor die is attached to and electrically connected to a pad in the first inter-metal dielectric layer by a connector. A molding material layer is disposed on the first inter-metal dielectric layer encapsulating the optical sensor die. A second inter-metal dielectric layer is disposed on the molding material layer. An opening extends through the molding material layer between the first inter-metal dielectric layer and the second inter-metal dielectric layer. The opening is filled or lined with conductive material electrically connecting the first inter-metal dielectric layer and the second inter-metal dielectric layer.

In an aspect, a package includes an inorganic substrate with a first inter-metal dielectric layer disposed on a first surface of the inorganic substrate. An optical sensor die is attached and electrically connected to a pad in the first inter-metal dielectric layer by a connector. A molding material layer disposed on the first inter-metal dielectric layer encapsulates the optical sensor die. A second inter-metal dielectric layer is disposed on a second surface of the inorganic substrate opposite the first surface. A through-glass via connects the first inter-metal dielectric layer and the second inter-metal dielectric layer.

In an aspect, a package includes an inorganic substrate that is a piece of glass with a recess therein extending through a back surface of the piece of glass. A first inter-metal dielectric layer disposed on a first surface of the recess. An optical sensor die is disposed in the recess. The optical sensor die is attached and electrically connected to a pad in the first inter-metal dielectric layer by a connector. A molding material layer disposed in the recess encapsulates the optical sensor die. A second inter-metal dielectric layer is disposed on the back surface of the inorganic substrate along a perimeter of the recess. A metal trace disposed on a side of the recess connects the first inter-metal dielectric layer and the second inter-metal dielectric layer.

In an aspect, a package includes an inorganic substrate that is a piece of glass. A recess extends through a back surface of the piece of glass. A first inter-metal dielectric layer is disposed on a first surface of the recess. An optical sensor die is disposed in the recess. The optical sensor die is attached and electrically connected to a pad in the first inter-metal dielectric layer by a connector. A molding material layer disposed in the recess encapsulates the optical sensor die. A second inter-metal dielectric layer is disposed on the back surface of the piece of glass along a perimeter of the recess. A metal trace disposed on a side of the recess connects the first inter-metal dielectric layer and the second inter-metal dielectric layer. A third inter-metal dielectric layer is disposed on a top surface of the piece of glass. A conductive material disposed in a through-glass via connects the first inter-metal dielectric layer and the second inter-metal dielectric layer.

In an aspect, a package includes an optical sensor die, an application specific integrated circuit die, and a glass substrate. The optical sensor die is arranged in a stack above the application specific integrated circuit die. The stack is coupled to the glass substrate.

The details of one or more implementations are set forth in the accompanying drawings and the description below. Other features will be apparent from the description and drawings, and from the claims.

### BRIEF DESCRIPTION OF THE DRAWINGS

FIG. 1A illustrates a wire-free optical sensor package in which an optical sensor die is disposed on an inorganic substrate, in accordance with the principles of the present disclosure.

FIG. 1B illustrates another a wire-free optical sensor package in which an optical sensor die is disposed on an inorganic substrate, in accordance with the principles of the present disclosure.

FIG. 2 illustrates an example wire-free optical sensor package in which through glass vias (TGVs) electrically connect an optical sensor die to a ball grid array of solder balls, in accordance with the principles of the present disclosure.

FIGS. 3A, 3B, 3C, and 3D each illustrate a cross-sectional view of example wire-free optical sensor packages in which an optical sensor die is disposed in a recess in an inorganic substrate, in accordance with the principles of the present disclosure.

FIGS. 4A and 4B illustrate a cross-sectional views of wire-free optical sensor packages in which a cover is disposed above an optical sensor die and forms an air cavity with a vent above the die.

FIGS. 5A, 5B, and 5C illustrate cross-sectional view of wire-free optical sensor packages with package features designed to reduce flare.

FIG. 6 illustrates an example method for fabricating a wire-free optical sensor package.

FIGS. 7A through 7H illustrate cross-sectional views of an inorganic substrate being processed through multiple steps for making a wire-free optical sensor package, according to the method of FIG. 6.

FIG. 8 illustrates another example method for fabricating a wire-free optical sensor package.

FIGS. 9A through 9G illustrate cross-sectional views of an inorganic substrate being processed through multiple steps for making a wire-free optical sensor package, according to the method of FIG. 8.

FIG. 10 illustrates yet another example method for fabricating a wire-free optical sensor package.

FIGS. 11A through 11F illustrate cross-sectional views of an inorganic substrate being processed through multiple steps for making a wire-free optical sensor package, according to the method of FIG. 10.

FIG. 12 shows an example wire-free optical sensor package that includes an optical sensor die coupled to, and arranged in a stack above an ASIC die.

FIG. 13 illustrates a cross-sectional view of a stack of an optical sensor die and ASIC die disposed on a glass substrate in an optical sensor package.

In the drawings, which are not necessarily drawn to scale, like reference symbols or alpha numerals may indicate like and/or similar components in different views. The drawings illustrate generally, by way of example, but not by way of limitation, various implementations discussed in the present disclosure. Reference symbols or alpha-numeral identifiers shown in one drawing may not be repeated for the same, and/or similar elements in related views. Reference symbols or alpha-numeral identifiers that are repeated in multiple drawings may not be specifically discussed with respect to each of those drawings but are provided for context between related views. Also, not all like elements in the drawings are specifically referenced with a reference symbol or an alpha-numeral identifier when multiple instances of an element are illustrated.

### DETAILED DESCRIPTION

An optical sensor can be fabricated on a semiconductor device die includes an optically active surface area (OASA) including an x-y array of pixel sensors responsible for converting a light and color spectrum into electrical signals. In some implementations, the optical sensor can be a complementary metal-oxide semiconductor (CMOS) pixel sensor. In some implementations, each pixel sensor in the array of pixel sensors may, for example, include a photo diode or a photo transistor that senses and converts incident light into an electrical signal. The OASA of an optical sensor may also include a color filter array (CFA). A CFA may be a mosaic of tiny color filters coupled to the pixel sensors to capture color information. For example, a Bayer RBG color filter or mosaic may include a pattern of red (R), blue (B) and green (G) color filters to capture color information related to the R, B and G colors. The OASA of an optical sensor may also include a microlens array to help funnel incoming light into each pixel to increase the sensitivity of the optical sensor. In some implementations, the microlens array can be an x-y array of microlenses.

A pixel can refer to either an individual pixel sensor device (e.g., a photo diode or a photo transistor), to the individual pixel sensor and an associated color filter, or collectively to the individual pixel sensor, the associated color filter, and an associated microlens. The individual pixel sensor device can be a photo diode or a photo transistor.

Newer industrial and consumer applications, for example, automotive applications such as advanced driver assistance systems (ADAS) and autonomous driving (AD) systems, can include other circuitry in the same integrated circuit (IC) package as the optical sensor die for improved imaging performance. The other circuitry may include an optical signal processor (ISP) or an application specific integrated circuit (ASIC). The ISP or the ASIC die, can be coupled to, or combined with the optical sensor die in a package. In example implementations, an IMD layer that is disposed on the optical sensor die and or the ASIC die may include at least a metal level of a redistribution layer of the optical sensor die.

The devices of an optical sensor package may be fabricated in a semiconductor die (optical sensor die), for example, by wafer-level processing steps, and coupled to circuitry such as an ASIC. The ASIC can include, for example, a driver circuit and an A/D converter. The ASIC circuits may be fabricated on a same semiconductor die as the devices for detecting light intensity, or on a separate ASIC die coupled to the optical sensor die. In some implementations, the optical sensor package may include multiple semiconductor dies of diverse types. For example, in a hybrid die package configuration, the optical sensor package may include a silicon carbide (SiC) device die and a silicon device die.

This disclosure describes a wire-free optical sensor package (e.g., a ball grid array (BGA) package) in which a semiconductor optical sensor die is mounted on an amorphous (non-crystalline) solid inorganic substrate. The inorganic substrate may, for example, be a silicate-based substrate (e.g., a glass substrate). In example implementations, the glass substrate may be a borosilicate glass (such as Pyrex or Kimax). The borosilicate glass substrate may have a coefficient of thermal expansion (CTE) of about 3 ppm/K. In contrast, plastic, or organic substrates (e.g., BT substrates) that are used, for example, in iBGA packages, have CTEs of about 10 to 14 ppm/K. The low CTE and the rigidity of the glass substrate in the disclosed optical sensor packages may help avoid issues with die tilt and package warp that are seen, for example, in packages which use plastic or organic substrates (such as in iBGA packages).

The wire-free aspect of the optical sensor package implies that there are no wires connecting the optical sensor die to the lead frames or the external terminals of the package. Wire bonding steps are not needed to connect the optical sensor die to the lead frames or the external terminals of the package. The wire-free aspect of the optical sensor package can save space, reduce the size of the package, and simplify fabrication of the package.

In example implementations, an optical sensor die is disposed on a top surface of an inorganic substrate or in a recess in the top surface of the inorganic substrate. The inorganic substrate may, for example, be a glass substrate. The glass substrate may include inter-metal dielectric (IMD) layer or layers disposed on its surfaces (e.g., the top surface and a bottom surface). The IMD layers may include traces, wiring, and metal pads for redistributing electrical signals to and from the optical sensor die.

Further, the glass substrate may include through-substrate vias (e.g., through-glass vias (TGVs)) extending from the top surface through a thickness of the glass substrate to the bottom surface of the glass substrate. In example implementations some of the TGVs may be filled or lined with electrically conductive material (e.g., copper) to electrically connect the IMD layers on the top surface and the bottom surface of the glass substrate. The IMD layer on the bottom surface may include conductive pads (e.g., metal pads) on which solder balls can be disposed to form a ball grid array (BGA) for external contact to the optical sensor die. In some example implementations, some of the TGVs may not be connected to the optical sensor die, but may be purposed for heat dissipation and/or strength uniformity across the glass substrate.

In some example implementations, an optical sensor die is disposed in a recess in a top surface of a block of encapsulation material (e.g., mold material). The block of encapsulation material may include one or more signal redistribution layers (RDLs) including, for example, an inter-metal dielectric layer or layers disposed on its surfaces (e.g., a top surface and a bottom surface). The IMD layers may include traces, wiring, and conductive pads (e.g., metal pads) for redistributing electrical signals to and from the optical sensor die.

Further, the block of encapsulation material may include through-encapsulant vias (TEVs) (also called through-mold vias (TMVs) herein) extending from a top surface through a thickness of the block of encapsulation material to a bottom surface of the slab of encapsulation material. In example implementations, some of the TEVs (or TMVs) may be filled with electrically conductive material to electrically connect the IMD layers on the top surface and the bottom surface of the block. The IMD layer on the bottom surface may, for example, include conductive pads on which solder balls can be disposed to form a ball grid array (BGA) for external contact to the optical sensor die. In some example implementations, some of the TEVs or TMVs may not be connected to the IMD layers on the top surface or the bottom surface of the block, but may be purposed for heat dissipation and/or strength uniformity across the block of encapsulation material.

An inorganic substrate may function as a cover or lid placed over the top surface of the encapsulation material to enclose the optical sensor die. In some instances, the cover may form an enclosed air cavity above an optically active surface area (OASA) of the optical sensor die.

In example implementations, the cover (e.g., a glass cover) may be transparent to light over at least a portion of a range of wavelengths detected or sensed by the OASA of the optical sensor die.

In some instances, for very large die (e.g., for a 15 Mega Pixel(MP), 2.1 um pixel die, having a size of about 12.2 mm×7.2 mm=87 mm2), the glass cover may include holes or vents to prevent buildup of air pressure in the air cavity above the optical sensor die. The holes or vents may have sufficiently small cross-sectional areas (e.g., diameters) such that surface tension prevents ingress of external fluids into the air cavity. In some example implementations, the glass cover may be placed in direct contact with the optical sensor die such that no air gap or air cavity is formed above the optical sensor die.

Further, in some implementations, a black dielectric (with high absorption and low reflection of visible and infrared light) may be patterned along the edges of the cover. This may help mitigate flare in the optical sensor die package.

An optical sensor converts light rays into an electronic signal. The purpose of an optical sensor is to measure a physical quantity of light and, depending on the type of sensor, translate the physical quantity of light into a form that is readable by an integrated measuring device. An optical sensor used as an image sensor or imager is a sensor that detects and conveys information used to form an image. Optical sensors are used in electronic imaging devices of both analog and digital types. These electronic imaging devices may include digital cameras, camera modules, camera phones, optical mouse devices, medical imaging equipment, night vision equipment such as thermal imaging devices, radar, sonar, etc. As technology changes, electronic and digital imaging tends to replace chemical and analog imaging. The two main types of digital image sensors are the charge-coupled device (CCD) and the active-pixel sensor (CMOS sensor), fabricated in complementary MOS (CMOS) or N-type MOS (NMOS) technologies.

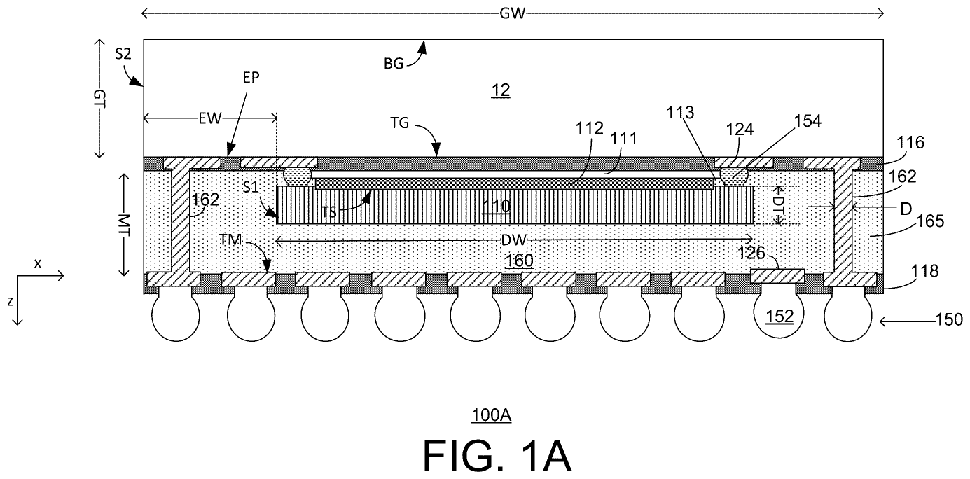

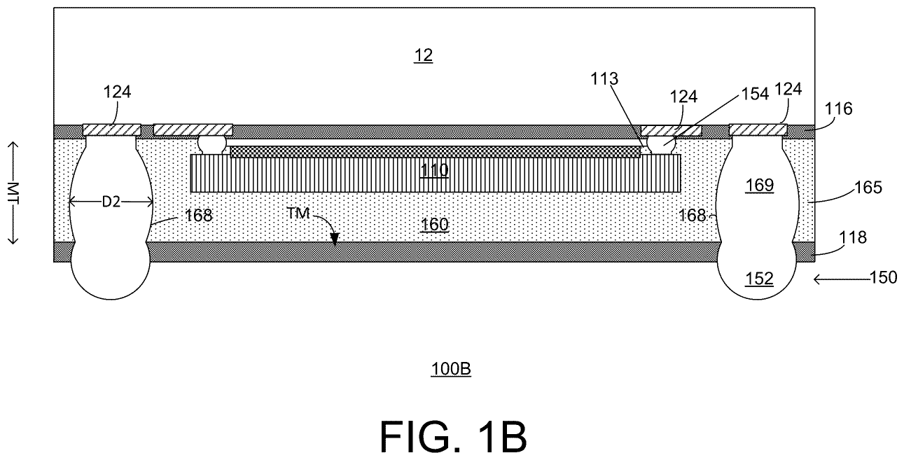

FIG. 1A shows a cross-sectional view of a wire-free optical sensor package 100A in which an optical sensor die 110 is disposed on an inorganic substrate (e.g., a glass substrate 12), in accordance with the principles of the present disclosure.

In wire-free optical sensor package 100A, optical sensor die 110 may, for example, be a semiconductor die with an optically active surface area (e.g., OASA 112) fabricated on a top surface of a layer of semiconductor material. The layer of semiconductor material may, for example, have a thickness DT (in a-z direction) and a width DW (e.g., in an x direction). The layer of semiconductor material may, for example, be silicon. OASA 112 may occupy a portion of a top surface (TS) of the semiconductor die. Portions of the top surface adjacent to OASA 112 may include device contact pads (e.g., pad 113) for making electrical connection to devices in optical sensor die 110.

In wire-free optical sensor package 100A, optical sensor die 110 is mounted, for example, in a flip chip orientation on an inorganic substrate (e.g., glass substrate 12). Glass substrate 12 may, for example, be a rectangular piece (also can be referred to as a portion) of glass with a thickness GT (e.g., in the z direction) and a width GW (e.g., in the x direction). Glass substrate 12 may, for example, be a borosilicate glass. An inter-metal dielectric layer (IMD layer 116) may be disposed on a top surface TG of glass substrate 12. IMD layer 116 may include conductive traces or pads (e.g., metal pad 124) that can form a signal redistribution layer for connection to the device contact pads (e.g., pad 113) of optical sensor die 110. In example implementations, the optical sensor die may have a smaller area than the area of the glass substrate 12 (e.g., a die width DW may be less than a glass substrate width GW). An edge portion (EP) of glass substrate 12 (extending, for example, from a side S1of the die to a side S2 of the glass substrate) may not be covered by the die. Edge portion EP may, for example, have a width EW (e.g., in the x direction).

Optical sensor die 110 may be mounted on (e.g., attached or bonded to) glass substrate 12, for example, in a flip chip orientation with a non-wire or wire-free connector (e.g., connector 154) connecting device contact pads (e.g., pad 113) of the optical sensor die to the die signal redistribution layer (e.g., IMD layer 116) formed on the top surface TG of the glass substrate. In example implementations, the glass substrate may be transparent to light over at least a portion of a range of wavelengths detected or sensed by the OASA of the optical sensor die. Light passing through the glass substrate may be incident on and sensed by the OASA of the optical sensor die.

In some implementations, wire-free connector 154 may include a solder ball that connects device contact pads (e.g., pad 113) to the conductive traces or pads (e.g., metal pad 124) in IMD layer 116. In some other example implementations, connector 154 may include a gold bump, a solder micro-bump, or a copper pillar.

In example implementations, the dielectric in IMD layer 116 may be an optically transparent dielectric. With the optical sensor die 110 mounted in the flip chip orientation, an air cavity 111 may be formed between glass substrate 12 and OASA 112 of the optical sensor die 110.

A molding material layer 160 (e.g., an epoxy, or a molding material) may be disposed on the top surface of the glass substrate to encapsulate optical sensor die 110 and portions EP of IMD layer 116 on the surface of glass substrate 12 (that extends beyond the width DW of the die). Molding material layer 160 may form a mold body 165. The mold body may be shaped, for example, as a rectangular block of thickness MT disposed on IMD layer 116 (on surface TG of glass substrate 12). A second inter-metal dielectric layer (e.g., IMD layer 118) may be disposed on a top surface TM of mold body 165.

IMD layer 118 may include a plurality of pads (e.g., metal pad 126). A plurality of through-mold vias (e.g., TMV 162) filled or lined with conductive material may connect conductive pads (e.g., metal pad 124) in IMD layer 116 on the top surface TG of glass substrate 12 to the conductive pads (e.g., metal pad 126) on the top surface of mold body 165. In example implementations, the conductive material filling TMV 162 may be a metal or a metal alloy (e.g., copper). Solder balls (e.g., solder balls 152) may be disposed on (attached to) the conductive pads (e.g., metal pad 126) to form a ball grid array (e.g., BGA 150) of solder balls as the external terminal contacts of wire-free optical sensor package 100A.

In example implementations, the TMVs (e.g., TMVs 162) that connect conductive pads (e.g., metal pad 124) in IMD layer 116 to conductive pads (e.g., metal pad 126) in IMD layer 118 may be formed by anisotropic etching (e.g., dry, or reactive ion etching) or by laser drilling. Such a TMV may have vertical walls and a small diameter D. Diameter D may, for example, be in a range of 0.1 mm to 1.0 mm.

In some example implementations, isotropic etching (e.g., wet etching) or other material removal techniques may be used to create openings in mold body 165 to access conductive pads (e.g., metal pad 124) in IMD layer 116. The openings may have non-vertical walls and have a larger diameter than diameter D of the TMV 162 shown in FIG. 1A.

FIG. 1B illustrates another example wire-free optical sensor package 100B in which an optical sensor die is disposed on an inorganic substrate, in accordance with the principles of the present disclosure.

In wire-free optical sensor package 100B, as shown in FIG. 1B, metal pad 124 in IMD layer 116 may be exposed at the top surface TM of mold body 165 by openings (e.g., opening 168) extending, for example, from metal pad 124 through the thickness MT of mold body 165 to the top surface TM. Opening 168 may be formed, for example, by contact masking and patterning of mold body 165 and wet etching through the thickness MT of mold body 165. Opening 168 may have non vertical walls and a diameter D2 which is larger than a diameter that can be obtained by dry or reactive ion etching (e.g., larger than diameter D of the TMV 162 shown in FIG. 1A).

Opening 168 may be filled with solder 169 that connects metal pad 124 to solder balls (e.g., solder balls 152) that form the ball grid array (e.g., BGA 150) as the external terminal contacts of wire-free optical sensor package 100B.

In some example implementations of a wire-free optical sensor package, through-substrate vias (e.g. through-glass vias (TGVs)) may be used to electrically connect an optical sensor die disposed on a one side of an inorganic substrate to a ball grid array of solder balls disposed on an opposite side of the glass substrate.

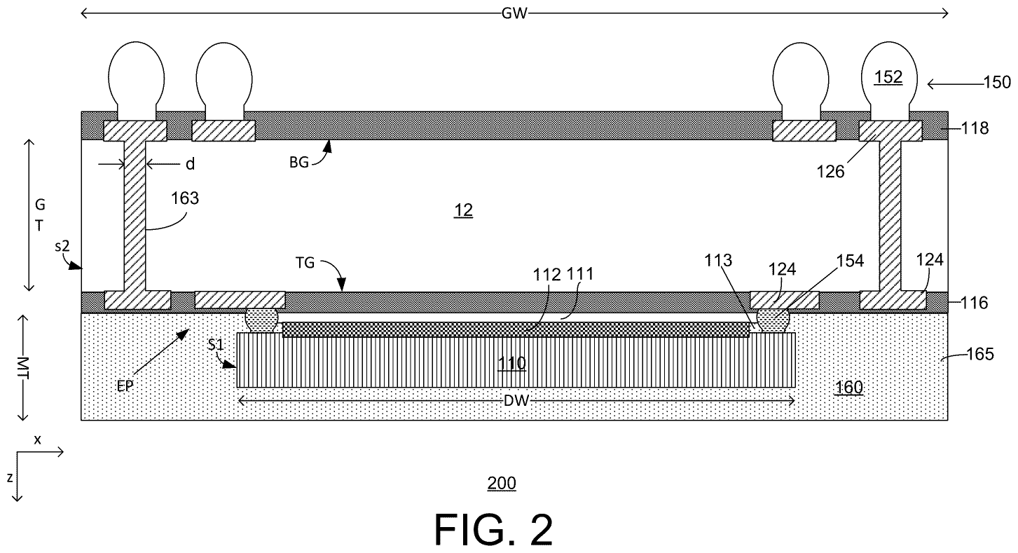

FIG. 2 shows a cross-sectional view of an example wire-free optical sensor package 200 in which TGVs electrically connect an optical sensor die disposed on a one side of an inorganic substrate to a ball grid array of solder balls disposed on an opposite side of the glass substrate.

As shown in FIG. 2, glass substrate 12 (like in FIG. 1A) has an IMD layer 116 disposed on a top surface TG and an IMD layer 118 disposed on a bottom surface BG. IMD layer 116 includes conductive traces and metal pads (e.g., metal pad 124) and IMD layer 118 includes conductive traces and metal pads (e.g., metal pad 126).

In optical sensor package 200, optical sensor die 110 may be mounted on (e.g., attached or bonded to) glass substrate 12, for example, in a flip chip orientation, with a non-wire or wire-free connector (e.g., connector 154) connecting device contact pads (e.g., pad 113) of the optical sensor die to the die signal redistribution layer (e.g., IMD layer 116) formed on the top surface TG of the glass substrate. A plurality of through-glass vias (e.g., TGV 163) filled or lined with conductive material may connect metal pad 124 on the top surface of glass substrate 12A to conductive pads (e.g., metal pad 126) on the bottom surface of glass substrate 12. In example implementations, TGV 163, which may be formed by anisotropic dry etching or laser drilling, may have vertical walls and a diameter (e.g., diameter d). Diameter d may be in the range of 0.1 mm to 2 mm. Solder balls 152 disposed on the conductive pads (e.g., metal pad 126) in IMD layer 118 on the bottom surface of glass substrate 12 may form the solder ball grid array (e.g., BGA 150) as the external contacts of the image sensor package.

Further, in optical sensor package 200, molding material layer 160 may be disposed on the optical sensor die 110 and on edge portions of the IMD layer 116 (e.g., edge portion EP of glass substrate 12 extending, for example, from a side S1 of the die to a side S2 of the glass substrate) to encapsulate optical sensor die 110 in a mold body 165.

In some example implementations of the wire-free optical sensor packages, an optical sensor die may be disposed in a recess in an inorganic substrate (e.g. a glass substrate).

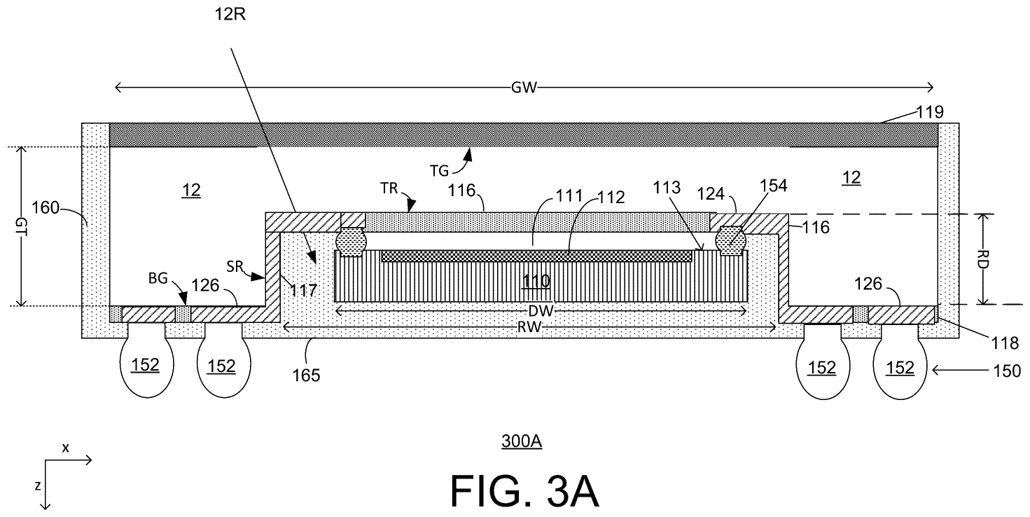

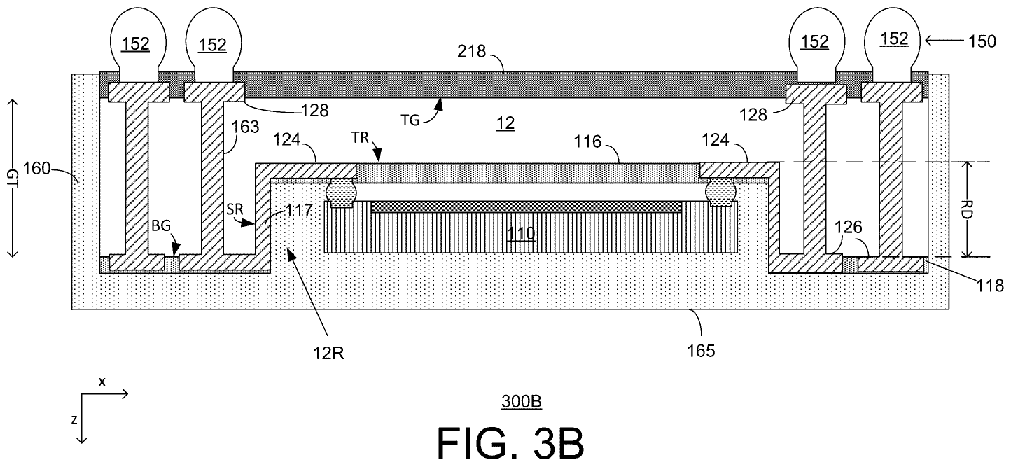

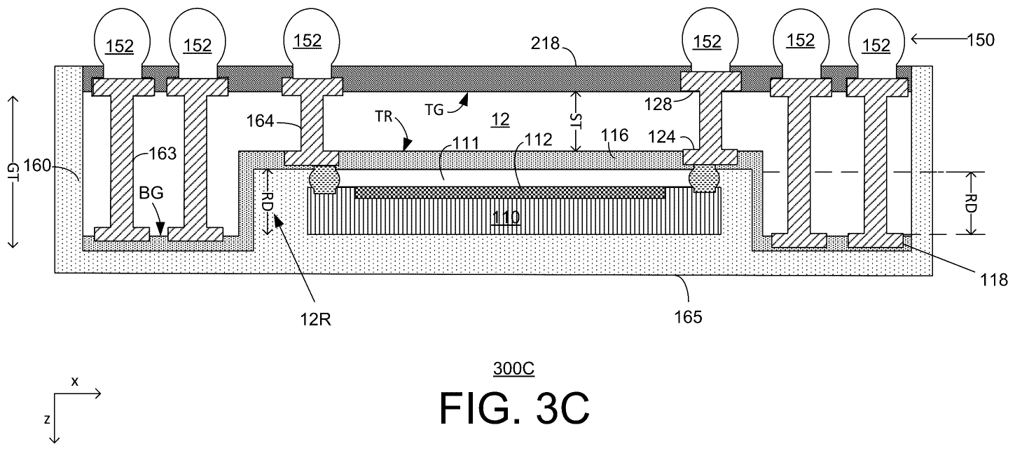

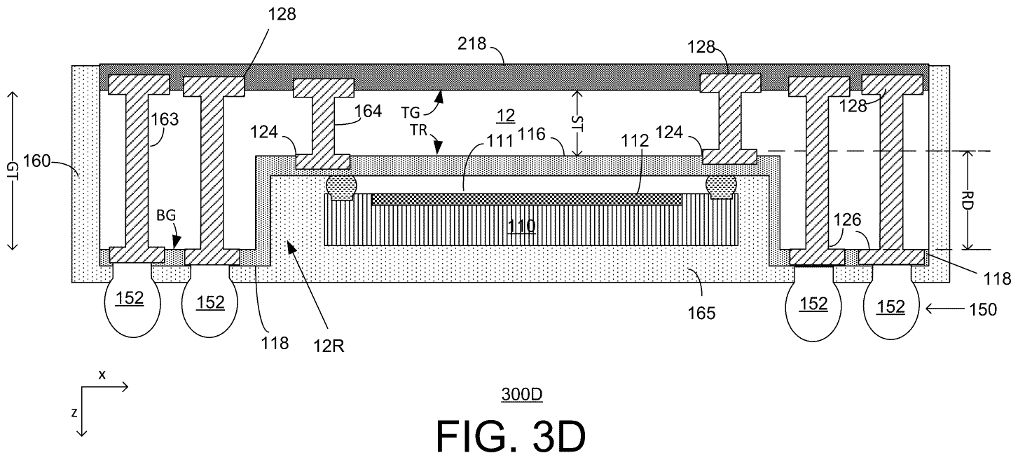

FIG. 3A shows a cross-sectional view of an example wire-free optical sensor package 300A in which an optical sensor die is disposed in recess in an inorganic substrate (e.g., glass substrate 12).

As shown in FIG. 3A, glass substrate 12 (as in FIG. 1A) may be a rectangular piece of glass having a width GW and a thickness GT. A recess 12R (e.g., a rectangular recess) having a width RW and a depth RD may be formed in the glass substrate through the backside (e.g., back surface BG). Width RW may be greater than width DW of die 110. An IMD layer 116 including conductive traces and pads (e.g., metal pad 124) may be disposed on a top surface TR (i.e., on the bottom of the recess). IMD layer 116 may include optically transparent dielectrics and/or metals. An IMD layer 118 may be disposed on a bottom surface BG of the glass substrate along a perimeter of recess 12R. IMD layer 118 includes conductive traces and pads (e.g., metal pad 126). A conductive trace (e.g., metal trace 117) may be disposed on sidewall SR of the recess to electrically connect the conductive traces and pads in IMD layer 116 to the conductive traces and pads in IMD layer 118.

In optical sensor package 300A, optical sensor die 110 may be mounted on (e.g., attached or bonded to) glass substrate 12, for example, in a flip chip orientation in recess 12R. With the die in a flip chip orientation, wire-free connector 154 may connect device contact pads (e.g., pad 113) of the optical sensor die to IMD layer 116 formed on the top surface TR of recess 12R. Solder balls 152 disposed on conductive pads (e.g., metal pad 126) in IMD layer 118 on the bottom surface of glass substrate 12 may form the solder ball grid array (e.g., BGA 150) as the external contacts of the optical sensor package.

Further, in optical sensor package 300A, a protective transparent dielectric layer 119 may be disposed on a top surface TG of glass substrate 12. Further, molding material layer 160 may be disposed on the sides of the glass substrate and in recess 12R to encapsulate optical sensor package 300A in a mold body 165.

In optical sensor package 300A shown in FIG. 3A, solder balls 152 that form the external contacts of the optical sensor package are disposed on conductive pads (e.g., metal pad 126) in IMD layer 118 on the bottom surface of glass substrate 12. In some other example optical sensor packages, the solder balls that form the external contacts of the optical sensor package may be disposed on the top surface of the glass substrate.

Further, molding material layer 160 may be disposed on the sides of the glass substrate and in recess 12R to encapsulate optical sensor package 300A in a mold body 165.

FIG. 3B shows a cross-sectional view of an example wire-free optical sensor package 300B in which an optical sensor die is disposed in a recess in an inorganic substrate (e.g., a glass substrate) and in which the solder balls that form the external contacts of the optical sensor package are disposed on the top surface of the glass substrate.

Optical sensor package 300B (like optical sensor package 300A) includes optical sensor die 110 disposed in a flip chip orientation in recess 12R in glass substrate 12. The signal redistribution layers for optical sensor die 110 in optical sensor package 300B (as in optical sensor package 300A) include IMD layer 116 disposed on a top surface TR of the recess 12R, and IMD layer 118 disposed on a bottom surface BG of the glass substrate along a perimeter of recess 12R. In optical sensor package 300B, the signal distribution layers for optical sensor die 110 further include an IMD layer 218 disposed on top surface TG of the glass substrate. IMD layer 116 may include conductive traces and pads (e.g., metal pad 124), IMD layer 118 may include conductive traces and pads (e.g., metal pad 126), and IMD layer 218 may include conductive traces and pads (e.g., metal pad 128). A conductive trace (e.g., metal trace 117) disposed on sidewall SR of the recess may electrically connect the conductive traces and pads in IMD layer 116 and the conductive traces and pads in IMD layer 118. Further, IMD layer 218 may be connected to IMD layer 118 by conductive material filled TGVs. (e.g., TGV 163) .

TGV 163 may extend through the thickness GT of the portion (piece) of glass substrate 12 outside recess 12R. TGV 163 may connect conductive pads (e.g., metal pad 126) in IMD layer 118 to conductive pads (e.g., metal pad 128) in IMD layer 218. Solder balls 152 may be disposed on the conductive pads (e.g., metal pad 128) to form the solder ball grid array (e.g., BGA 150) on the top surface TG as the external contacts for optical sensor package 300B.

Other example implementations of wire-free optical sensor packages in which an optical sensor die is disposed in a recess in an inorganic substrate (e.g., a glass substrate) may use yet further different configurations of TGVs to interconnect the various signal redistribution layers for the die in the package.

FIG. 3C shows a cross-sectional view of another example wire-free optical sensor package 300C in which an optical sensor die is disposed in a recess in an inorganic substrate and in which the solder balls that form the external contacts of the optical sensor package are disposed on the top surface of the glass substrate (like optical sensor package 300B, FIG. 3B).

In optical sensor package 300C, as in optical sensor package 300B, optical sensor die 110 is mounted in a flip chip orientation in recess 12R in glass substrate 12. The signal redistribution layers for optical sensor die 110 in optical sensor package 300C (as in optical sensor package 300B) include IMD layer 116 disposed on a top surface TR of the recess 12R, IMD layer 118 disposed on a bottom surface BG of the glass substrate along a perimeter of recess 12R, and an IMD layer 218 disposed on top surface TG of the glass substrate.

IMD layer 218 may be connected to IMD layer 118 by conductive material filled TGVs. (e.g., TGV 163) . TGV 163 may extend through the thickness GT of the portion (piece) of the glass substrate 12 outside recess 12R. TGV 163 may connect conductive pads (e.g., metal pad 126) in IMD layer 118 to conductive pads (e.g., metal pad 128) in IMD layer 218. Further in optical sensor package 300C, IMD layer 218 may be connected to IMD layer 116 by conductive material filled TGVs. (e.g., TGV 164) that extend through the thickness ST of a piece of the glass substrate 12 above (e.g., in the z direction) recess 12R.

Solder balls 152 may be disposed on the conductive pads (e.g., metal pad 128) to form the solder ball grid array (e.g., BGA 150) on the top surface TG as the external contacts for optical sensor package 300C.

FIG. 3D Shows a cross-sectional view of another example wire-free optical sensor package 300D in which an optical sensor die is disposed in a recess in an inorganic substrate (e.g. a glass substrate 12) and having a different configuration of connections between signal distribution layers for the optical sensor die than wire-free optical sensor packages 300A, 300B, or 300C. In wire-free optical sensor package 300D, the solder balls that form the external contacts of the optical sensor package are disposed on the bottom surface of the glass substrate (like optical sensor package 300A, FIG. 3A).

In optical sensor package 300D, as in optical sensor package 300C, optical sensor die 110 is mounted in a flip chip orientation in recess 12R in glass substrate 12. The signal redistribution layers for optical sensor die 110 in optical sensor package 300D (as in optical sensor package 300C) include IMD layer 116 disposed on a top surface TR of the recess 12R, IMD layer 118 disposed on a bottom surface BG of the glass substrate along a perimeter of recess 12R, and IMD layer 218 disposed on top surface TG of the glass substrate. IMD layer 218 may be connected to IMD layer 118 by conductive material filled TGVs (e.g., TGV 163) that extend through the thickness GT of glass substrate 12 (outside recess 12R). Further, IMD layer 218 also may be connected to IMD layer 116 by conductive material filled TGVs. (e.g., TGV 164) that extend through the thickness ST of the piece of glass substrate 12 (above recess 12R). Solder balls 152 may be disposed on the conductive pads (e.g., metal pad 126) in IMD layer 118 to form the solder ball grid array (e.g., BGA 150) on the bottom surface BG of the glass substrate as the external contacts for optical sensor package 300D.

In the foregoing optical sensor packages 100a, 100B, 200, 300A, 300B, 300C and 300D, the IMD layers (for example, IMD layer 116 and IMD layer 218) may be made of transparent dielectric materials to allow light to pass through the glass substrate and reach OASA 112 of the optical sensor die 110. In the various optical sensor packages, glass substrate 12 may enclose an air cavity 111 above OASA 112 of the optical sensor die, and may also serve as an inorganic cover or lid on the air cavity 111 above the optical sensor die.

In example implementations of a wire-free optical sensor package in which the glass substrate is disposed above optical sensor die 110, the glass substrate may serve as an inorganic cover or lid on the air cavity. At least one air vent hole may be disposed in the body of the glass substrate. The air vent hole may provide a path for air flow between the air cavity above the optical sensor die 110 and the ambience of the optical sensor package. The air vent hole (or holes) may prevent buildup of air pressure in the air cavity above the optical sensor. The air vent size (e.g., hole diameter) may be sufficiently small so that the surface tension of an external fluid (e.g., water, alcohol, etc.) will prevent the external fluid from entering the cavity through the air vent hole.

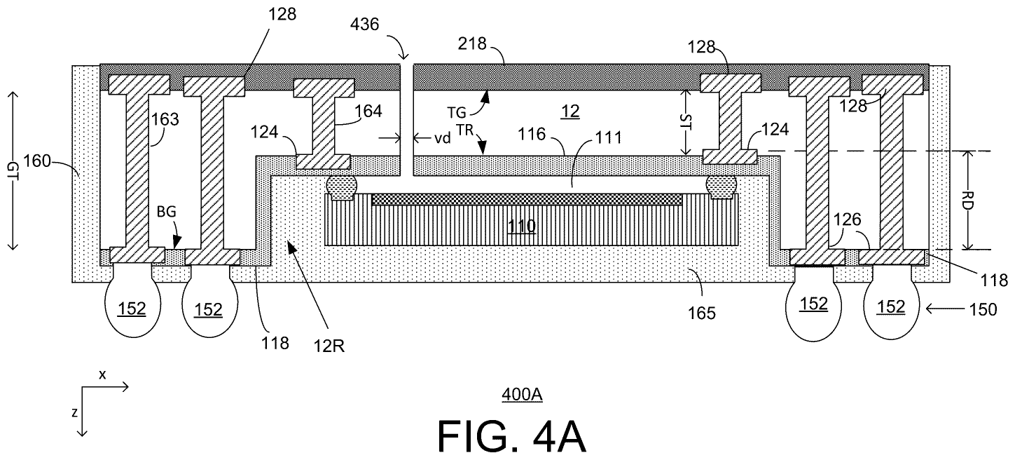

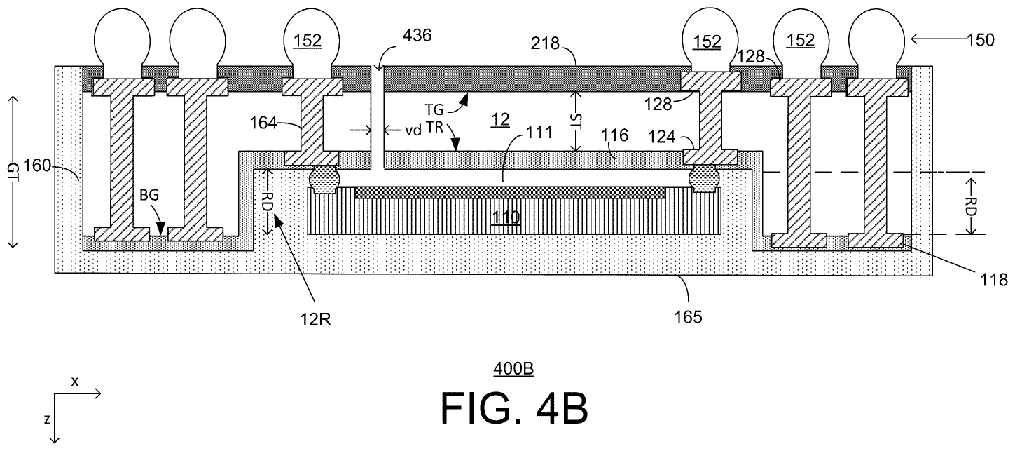

For example, FIG. 4A shows a cross-sectional view of a wire-free optical sensor package 400A in which, like in optical sensor package 300C (FIG. 3C), optical sensor die 110 is disposed in recess 12R in glass substrate 12. The glass substrate encloses an air cavity 111 above the die. Glass substrate 12 in wire-free optical sensor package 400A includes an air vent or passageway (e.g., hole 436) which extends vertically though through the thickness ST of a portion of the glass substrate 12 above (e.g., in the z direction) recess 12R. Hole 436 also extends through IMD layers 218 and 118 that may be disposed on the top surface of the glass substrate and the top surface of the recess.

Hole 436, which may have a diameter vd connects air cavity 111 to the outside of optical sensor package 400A. Hole 436 may prevent a buildup of air pressure in the air cavity above the sensor. The diameter vd of hole 436 may be sufficiently small to prevent external fluids from entering the cavity because of the surface tension of the fluids.

In optical sensor package 400A, solder balls 152 may be disposed on the conductive pads (e.g., metal pad 126) in IMD layer 118 to form the solder ball grid array (e.g., BGA 150) on the bottom surface BG of the glass substrate as the external contacts for optical sensor package 400A.

FIG. 4B shows a cross-sectional view of another optical sensor package 400B in which, like in optical sensor package 300D (FIG. 3D), optical sensor die 110 is disposed in recess 12R in glass substrate 12. The glass substrate encloses an air cavity 111 above the die. Glass substrate 12 in optical sensor package 400A includes an air vent or passageway (e.g., hole 436) which extends vertically though through the thickness ST of a portion of the glass substrate 12 above (e.g., in the z direction) recess 12R. Hole 436 also extends through IMD layers 218 and 118 that may be disposed on the top surface of the glass substrate and the top surface of the recess.

As in optical sensor package 400A, hole 436 in optical sensor package 400B connects air cavity 111 to the outside of optical sensor package 400B. Hole 436 may prevent a buildup of air pressure in the air cavity above the sensor.

In optical sensor package 400B, solder balls 152 may be disposed on the conductive pads (e.g., metal pad 128) in IMD layer 218 to form the solder ball grid array (e.g., BGA 150) on the top surface TG of the glass substrate as the external contacts for optical sensor package 400B.

In some implementations, the optical sensor packages described herein may include features that eliminate or reduce occurrences of flare in images collected by the optical sensor dies in the packages. For example, in some implementations, a black mask or coating may be disposed on the underside of the edges of the portion of the glass substate or the cover disposed above the optical sensor die to reduce occurrences of flare.

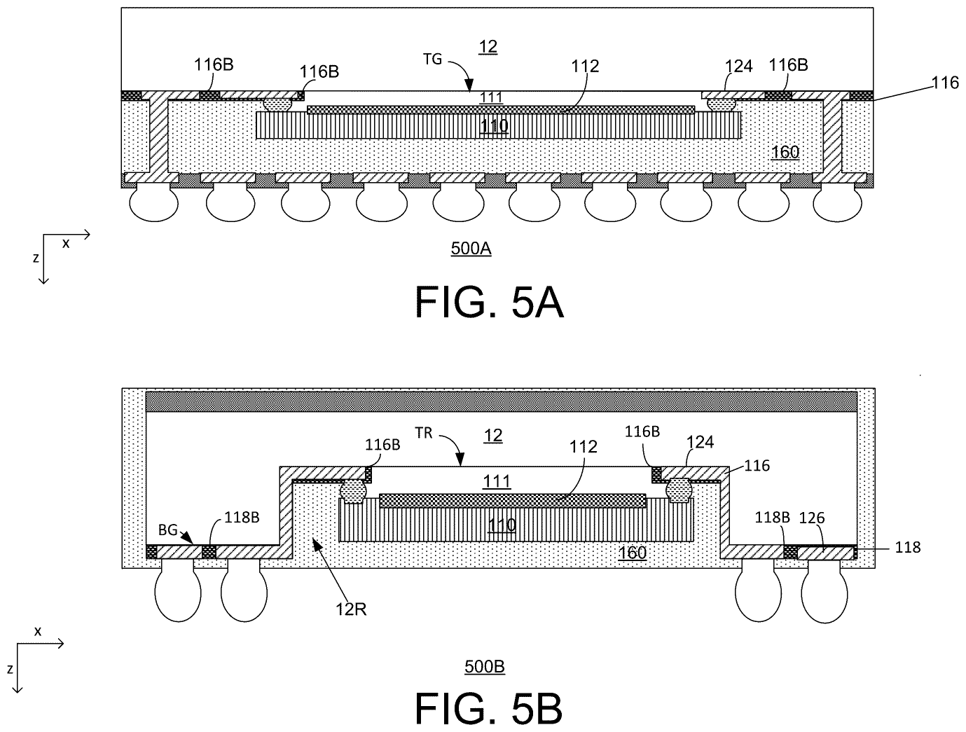

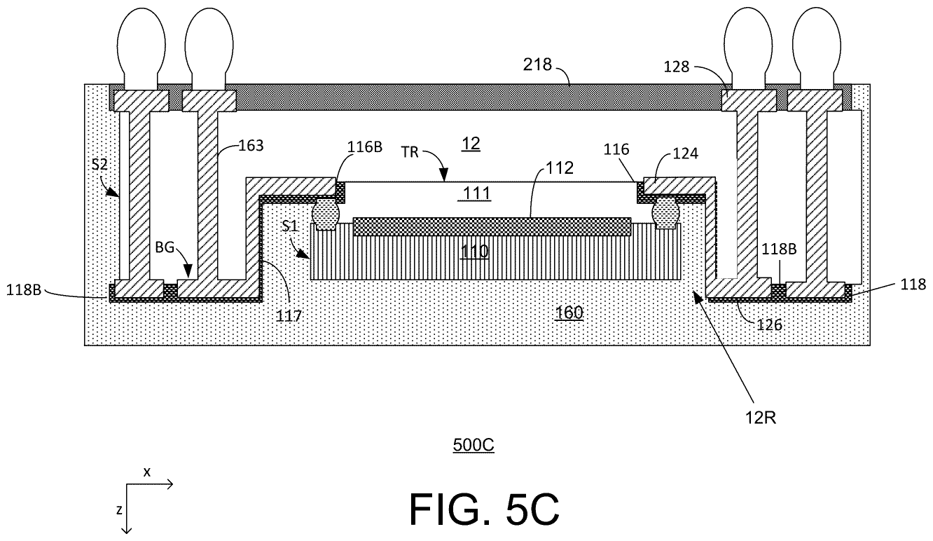

FIG. 5A shows a cross-sectional view of a wire-free optical sensor package 500A with a black-under-glass (BuG) feature (e.g., a black mask).

Wire-free optical sensor package 500A may (like wire-free optical sensor package 100A, FIG. 1A) include an optical sensor die 110 disposed on wire-free connector 154 on glass substrate 12. Wire-free connector 154 may be a solder ball that connects device contact pads (e.g., pad 113) to the conductive traces or pads (e.g., metal pad 124) in IMD layer 116. In some other example implementations, wire-free connector 154 may include a gold bump, a solder micro-bump, or a copper pillar.

The glass substrate may be held above the OASA 112 of the die by connector 154 to enclose air cavity 111. Encapsulating or molding material layer 160 may be disposed on a side (S1) of the die and on the glass cover.

In wire-free optical sensor package 500A, the signal redistribution layer for the optical sensor die 110 includes IMD layer 116 disposed on a top surface TG of glass substrate 12. IMD layer 116 may be patterned to include IMD portions 116B. IMD portions 116B may be patterned as a mask that has a black color. IMD portion 116B may be formed by a paint, an epoxy, a dielectric, or other non-transparent material with high absorption and low reflection of visible and infrared light.

In FIG. 5A, stray light that may cause flare includes, for example: light rays incident on the edge of the portion of glass substrate above the optical sensor die and light rays incident on OASA 112 at low angles through the IMD layer 116. IMD portions 116B that have black color may absorb and prevent scattering of these light rays on to the OASA of the optical sensor die to reduce or eliminate occurrences of flare.

FIG. 5B shows a cross-sectional view of another wire-free optical sensor package 500B with a black-under-glass (BuG) feature (e.g., a black mask).

Wire-free optical sensor package 500B may (like optical sensor package 300A, FIG. 3A) include an optical sensor die 110 disposed in a recess 12R in glass substrate 12. A portion of the glass substrate may be held above the OASA of the die by wire-free connector 154 to enclose air cavity 111. Wire-free connector 154 may be a solder ball that connects device contact pads (e.g., pad 113) to the conductive traces or pads (e.g., metal pad 124) in IMD layer 116. The signal redistribution layers for optical sensor die 110 in optical sensor package 500B (as in optical sensor package 300A) include IMD layer 116 disposed on a top surface TR of the recess 12R, and IMD layer 118 disposed on a bottom surface BG of the glass substrate along a perimeter of recess 12R. IMD layer 116 may include conductive traces and pads (e.g., metal pad 124) and, IMD layer 118 may include conductive traces and pads (e.g., metal pad 126),

Encapsulating or molding material layer 160 may be disposed on a side (S1) of the die and on the glass cover.

The IMD layer 116 may be patterned to include IMD portions 116B. Further, IMD layer 118 may be patterned to include IMD portions 118B. IMD portions 116B and 118B may be patterned as black masks that have a black color. IMD portions 116B and 118B may be formed by a paint, an epoxy, a dielectric, or other non-transparent material with high absorption and low reflection of visible and infrared light.

In FIG. 5B, stray light that may cause flare includes, for example: light rays incident on the edges of recess 12R and light rays incident on OASA 112 at low angles through the IMD layers 116 and 118. IMD portions 116B and 118B that have black color may absorb and prevent scattering of these light rays on to the OASA of the optical sensor die to prevent occurrences of flare.

FIG. 5C shows a cross-sectional view of yet another wire-free optical sensor package 500C with a black-under-glass (BuG) feature (e.g., a black mask).

Wire-free optical sensor package 500C may (like optical sensor package 300B, FIG. 3B) include an optical sensor die 110 disposed in a recess 12R in glass substrate 12. The glass substrate may be held above the OASA of the die by wire-free connector 154 to enclose air cavity 111. Encapsulating or molding material layer 160 may be disposed on a side (S1) of the die and on sides (S2) of the glass substrate.

In a wire-free optical sensor package 500C, the signal redistribution layer for the optical sensor die 110 (as in optical sensor package 300B) include IMD layer 116 disposed on a top surface TR of the recess 12R, and IMD layer 118 disposed on a bottom surface BG of the glass substrate along a perimeter of recess 12R, and an IMD layer 218 disposed on top surface TG of the glass substrate. IMD layer 116 may include conductive traces and pads (e.g., metal pad 124), IMD layer 118 may include conductive traces and pads (e.g., metal pad 126), and IMD layer 218 may include conductive traces and pads (e.g., metal pad 128). A conductive trace (e.g., metal trace 117) disposed on sidewall SR of the recess may electrically connect the conductive traces and pads in IMD layer 116 and the conductive traces and pads in IMD layer 118. Further, IMD layer 218 may be connected to IMD layer 118 by conductive material filled TGVs. (e.g., TGV 163) .

IMD layer 116 may be patterned to include IMD portions 116B. Further, IMD layer 118 may be patterned to include IMD portions 118B. IMD portions 116B and 118B may be patterned as black masks that have a black color. IMD portions 116B and 118B may be formed by a paint, an epoxy, a dielectric, or other non-transparent material with high absorption and low reflection of visible and infrared light. In wire-free optical sensor package 500C, stray light that may cause flare includes, for example, light rays incident on the edges of recess 12R and light rays incident on OASA 112 at low angles through the IMD layers 116 and 118. IMD portions 116B and 118B that have a black color may absorb and prevent scattering of these light rays on to the OASA of the optical sensor die to prevent occurrences of flare.

In example implementations, the wire-free optical sensor packages described herein may be fabricated using wafer-level processes and or die-level processes.

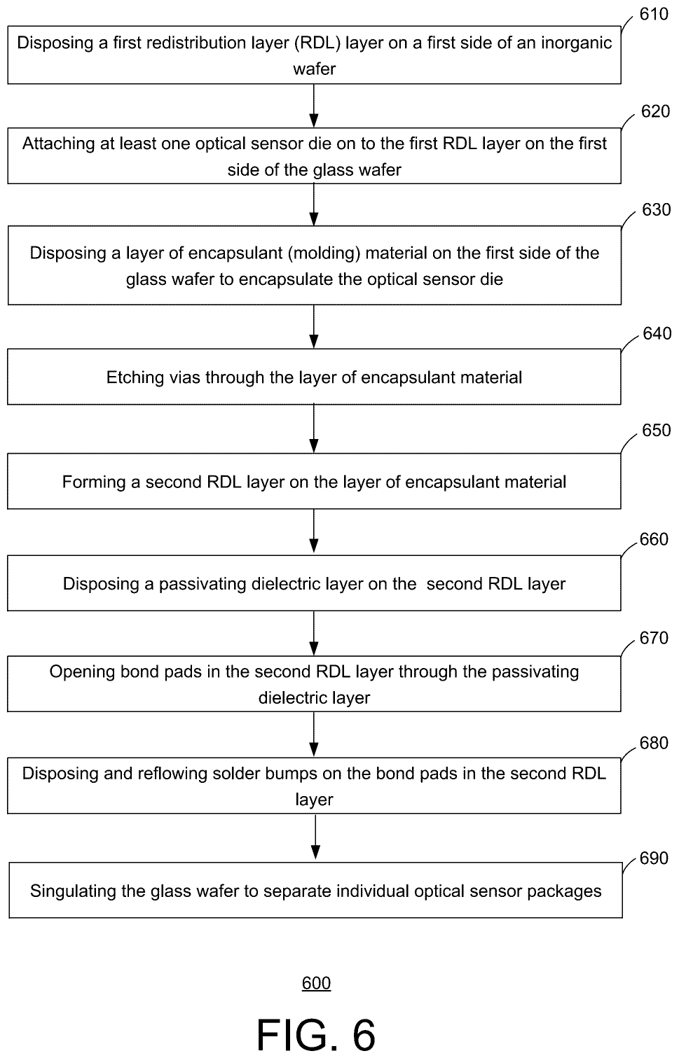

FIG. 6 shows an example method 600 that involves wafer-level and die-level processes for disposing semiconductor optical die on an inorganic substrate in a wire-free optical sensor package. The package may be configured as a ball grid array package with solder balls forming the external electrical contacts or terminals of the package (e.g., wire-free optical sensor package 100A, FIG. 1A).

Method 600 includes disposing a first redistribution layer (RDL) layer on a first side of an inorganic wafer (610). The inorganic wafer may, for example, be a glass wafer. The first RDL layer may be an inter-metal dielectric (IMD) layer including traces and pads for carrying signals to and from an optical sensor die. Method 600 further includes attaching (e.g., coupling) at least one optical sensor die on to the first RDL layer on the first side of the glass wafer (620). A pick-and-place die attach process may be used to place individual dies on the glass wafer. The at least one die may be placed upside down so that the OASA of the die is facing the first side. The at least one optical sensor die may be attached (bonded) to the glass wafer by a wire-free connector (e.g., a solder ball). In some other example implementations, the wire-free connector may include a gold bump, a solder micro-bump, or a copper pillar. The wire-free connector may electrically connect the first RDL to device contact pads next to the OASA on the optical sensor die. Further, the wire-free connector may raise the optical sensor die to a height above the surface of the RDL forming an air cavity between the OASA of the die and the glass wafer.

Next, method 600 include disposing a layer of encapsulant (molding) material on the first side of the glass wafer to encapsulate the at least one optical sensor die (630); and etching vias through the layer of encapsulant material (640). The etched vias (e.g., through-mold vias) in the layer of encapsulant material 640 may provide a pathway for electrically connecting the first RDL layer and a second RDL layer that may be later formed on the layer of encapsulant material.

Method 600 further includes forming the second RDL layer on the layer of encapsulant material (650). Forming the second RDL layer may include disposing tantalum/copper seeds on the layer of encapsulant material, photo resist coating and patterning, electroplating and resist strip. Th electroplating may include electroplating copper, or electroless Ni and immersion Au coating. The second RDL layer may include conductive material filling or lining the through-mold vias to connect the first RDL and second RDL layers. Method 600 further includes disposing a passivating dielectric layer on the second RDL layer (660) and opening bond pads in the second RDL layer through the passivating dielectric layer (670).

Method 600 further includes disposing and reflowing solder bumps on the bond pads in the second RDL layer (680). The solder bumps may form a ball grid array (BGA) of solder bumps. Method 600 further include singulating the glass wafer to separate individual optical sensor packages (690). Each individual optical sensor packages may include an optical sensor die attached to a portion of the glass wafer.

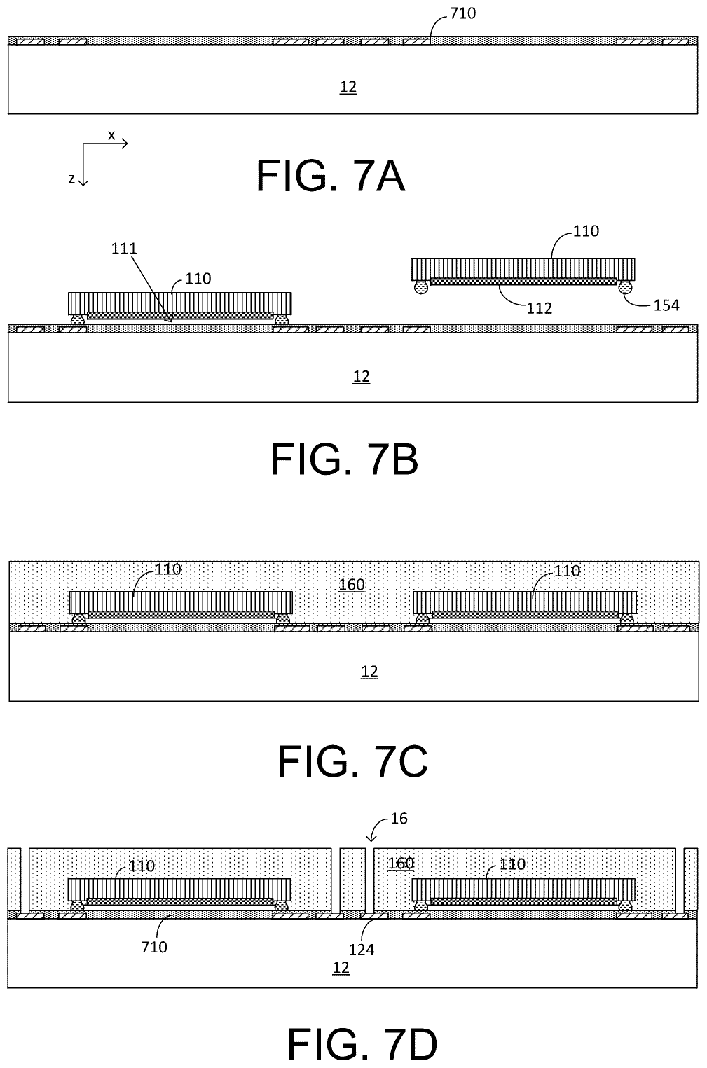

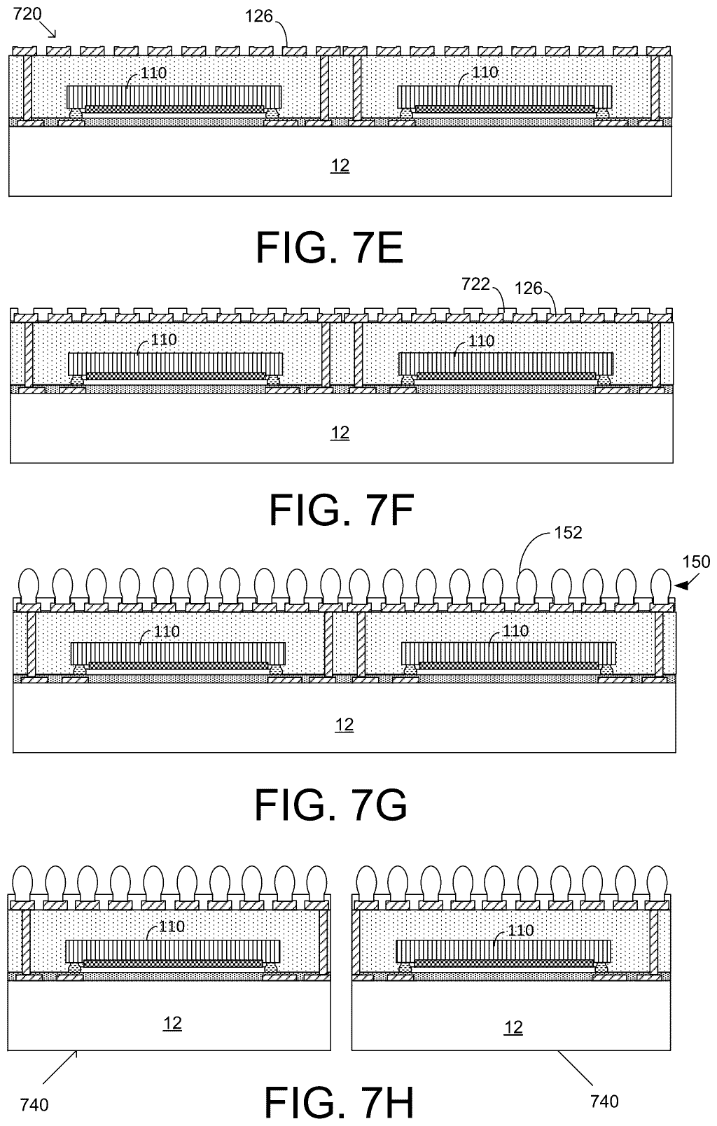

FIGS. 7A through 7H schematically illustrate cross-sectional views of an inorganic substrate and an optical sensor die being processed through multiple steps of a process for making a wire-free optical sensor package (e.g., according to method 600, FIG. 6).

FIG. 7A shows, for example, an initial stage of the process, a first RDL layer 710 is disposed on a first side of an inorganic substrate (a glass wafer or glass substrate 12). The first RDL layer may be an inter-metal dielectric (IMD) layer including traces and pads for carrying signals to and from an optical sensor die.

At a next stage of the process, as shown in FIG. 7B, at least one optical sensor die 110 is disposed on the first RDL layer on the glass wafer. The at least one optical sensor die 110 is placed upside down so that the OASA 112 of the die is facing the first side of the glass substrate. The at least one optical sensor die may be attached (bonded) to the glass wafer by a wire-free connector 154 (e.g., a solder ball). In some example implementations, the wire-free connector may include a gold bump, a solder micro-bump, or a copper pillar. The wire-free connector may electrically connect the first RDL layer to device contact pads (not shown) next to the OASA on the optical sensor die. Further, the wire-free connector may raise the optical sensor die to a height above the surface of the RDL forming an air cavity 111 between the OASA of the die and the glass wafer.

At a next stage of the process, as shown in FIG. 7C, an encapsulant (molding) material layer 160 is disposed on the first side of the glass wafer to encapsulate the at least one optical sensor die. At further stage of the process, as shown in FIG. 7D, through-mold vias 16 are etched through the encapsulant or molding material layer 160 to access conductive pads (e.g., metal pad 124) in the first RDL layer 710.

At a next stage of the process, as shown in FIG. 7E, metallization steps are conducted to form conductive pads (e.g., metal pad 126) of a second RDL layer 720 on the top of the encapsulant (molding) material layer 160. The metallization process also fills the through-mold vias 16 and electrically connects the first RDL layer to the second RDL layer.

At a further stage of the process, as shown in FIG. 7F, a passivation layer 722 is disposed on the second RDL layer 720, the conductive pads (e.g., metal pad 126) are exposed and cleaned in preparation for receiving solder bumps.

A next stage of the process includes disposing and reflowing solder bumps (e.g., solder balls 152) on the conductive pads (e.g., pads 126) in the second RDL layer. FIG. 7G shows an array of solder bumps (e.g., BGA 150) formed on the conductive pads (e.g., pads 126) in the second RDL layer. The array of solder balls can form the ball grid array of solder bumps forming the external contacts for each individual optical sensor die package.

At a further stage of the process as shown in FIG. 7H, the glass wafer may be singulated to separate individual optical sensor packages 740. Each individual optical sensor packages may include an optical sensor die 110 attached to a portion of the glass wafer.

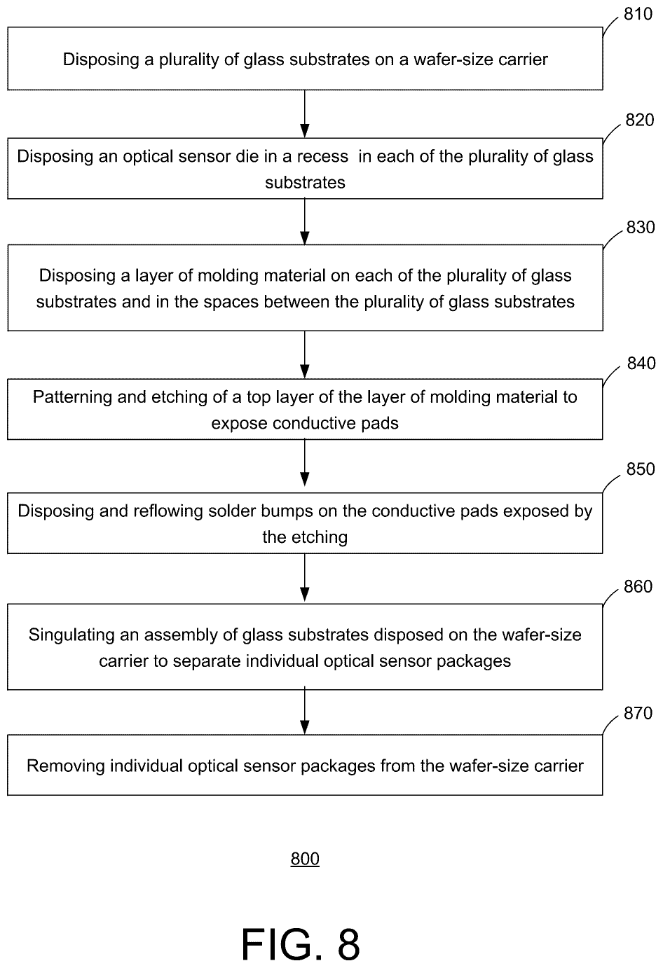

FIG. 8 shows an example method 800 that involves wafer-level and die-level processes for fabricating a wire-free optical sensor package including an optical sensor die disposed in a recess in an inorganic substrate (e.g., a glass substrate or wafer). Like in method 600, the resulting package of method 800 may be configured as a ball grid array package with solder balls forming the external electrical contacts or terminals of the package (e.g., wire-free optical sensor package 300A, FIG. 3A).

As shown in FIG. 3A, glass substrate 12 (as in FIG. 1A) may be a rectangular piece of glass having a width GW and a thickness GT. A recess 12R (e.g., a rectangular recess) having a width RW and a depth RD may be formed in the glass substrate through the backside (e.g., back surface BG). Width RW may be greater than width DW of die 110. An IMD layer 116 including conductive traces and pads (e.g., metal pad 124) may be disposed on a top surface TR (i.e., on the bottom of the recess). IMD layer 116 may include optically transparent dielectrics and/or metals. An IMD layer 118 may be disposed on a bottom surface BG of the glass substrate along a perimeter of recess 12R. IMD layer 118 includes conductive traces and pads (e.g., metal pad 126). A conductive trace (e.g., metal trace 117) may be disposed on sidewall SR of the recess to electrically connect the conductive traces and pads in IMD layer 116 to the conductive traces and pads in IMD layer 118.

Method 800 includes disposing a plurality of glass substrates on a wafer-size carrier (810). The wafer size-carrier may, for example, have a size compatible with that of a semiconductor wafer used in semiconductor device fabrication processes. The wafer-size carrier may, for example, be a wafer made of semiconductor material, a metal, or a ceramic. The glass substrate may be attached to the wafer-size carrier with a temporary adhesive. A pick-and-place technique may be used to individually dispose each of the plurality of glass substrates on the wafer-size carrier.

Method 800 further includes disposing an optical sensor die in a recess (e.g., recess 12R) in each of the plurality of glass substrates (820). Disposing the optical sensor die in the recess includes attaching the optical sensor die to the IMD layer 116 including conductive traces and pads (e.g., metal pad 124) on the top surface TR (i.e., on the bottom of the recess). A pick-and-place die attach process may be used to place an individual optical sensor die in the recess in each of the plurality of glass substrates. The optical sensor die may be placed upside down so that the OASA of the die is facing the bottom of the recess. The optical sensor die may be attached (bonded) to the glass wafer by a wire-free connector (e.g., a solder ball). In some example implementations, the wire-free connector may include a gold bump, a solder micro-bump, or a copper pillar. The wire-free connector may electrically connect the metal pad in IMD layer 116 to device contact pads next to the OASA on the optical sensor die. Further, the wire-free connector may raise the optical sensor die to a height above the surface of the RDL forming an air cavity between the OASA of the die and the glass substrate.

Next, method 800 include disposing a layer of encapsulant (molding) material on each of the plurality of glass substrates and in the spaces between the plurality of glass substrates (830). Method 800 may further include patterning and etching of a top layer of the layer of molding material (840). This patterning and etching may expose conductive pads (e.g., metal pad 126) in IMD layer 118 disposed on a bottom surface BG of the glass substrate along a perimeter of recess 12R.

Method 800 further includes disposing and reflowing solder bumps on the conductive pads exposed by the etching (850). The solder bumps formed on the conductive pads exposed on the bottom surface BG of the glass substrate may constitute a ball grid array (BGA) of solder bumps. Method 800 further includes singulating an assembly of glass substrates disposed on wafer-size carrier to separate individual optical sensor packages (860). The singulation may include sawing through the encapsulant material disposed in the spaces between the plurality of glass substrates disposed on the on the wafer-size carrier.

Method 800 may further include removing individual optical sensor packages from the wafer-size carrier (870).

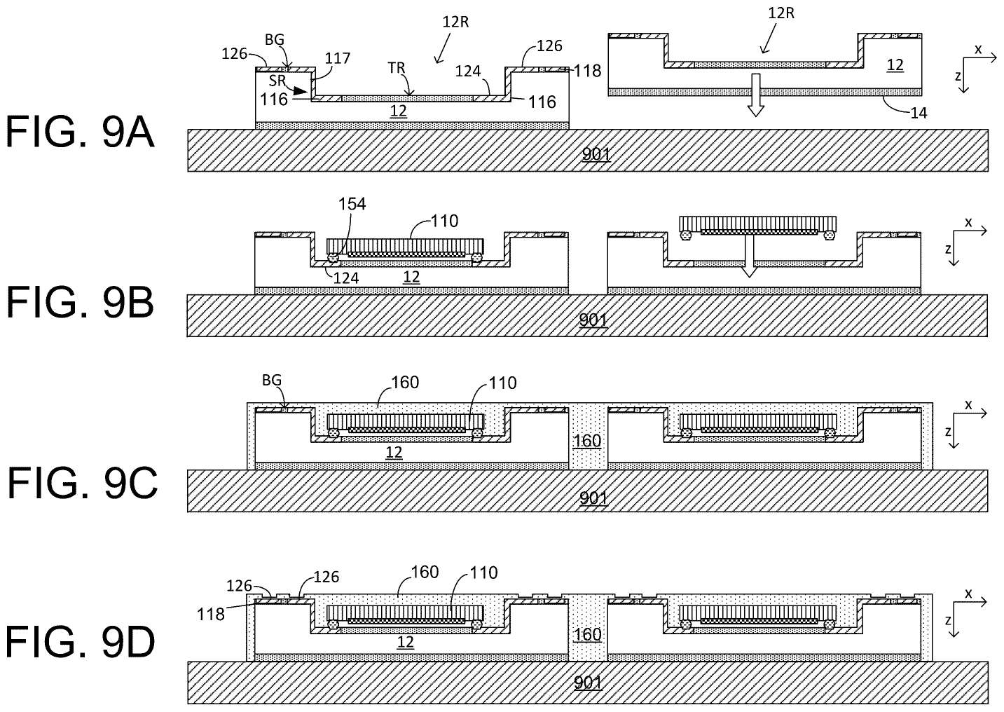

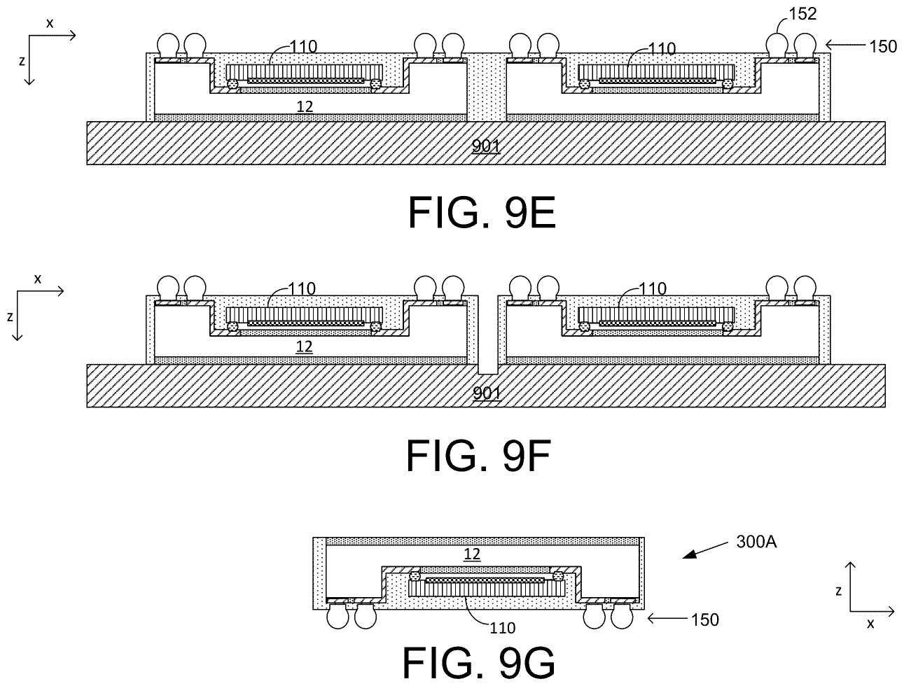

FIGS. 9A through 9G schematically illustrate cross-sectional views of glass substrates and optical sensor dies being processed through multiple process steps for making wire-free optical sensor packages (e.g., according to the method of FIG. 8).

FIG. 9A shows, for example, an initial stage of the process, in which a plurality of glass substrates (e.g., glass substrate 12) are disposed on and affixed to a carrier 901 using a temporary adhesive 14. Each of the glass substrates (e.g., substrate 12) may include a recess (e.g., recess 12R). Elements of a signal redistribution layer for an optical sensor die to be included in the optical sensor package may be disposed on surfaces of the glass substrate and the recess. For example, an IMD layer 116 including conductive traces and pads (e.g., metal pad 124) may be disposed on a top surface TR (i.e., on the bottom of the recess). An IMD layer 118 may be disposed on a bottom surface BG of the glass substrate along a perimeter of recess 12R. IMD layer 118 includes conductive traces and pads (e.g., metal pad 126). A conductive trace (e.g., metal trace 117) may be disposed on sidewall SR of the recess to electrically connect the conductive traces and pads in IMD layer 116 to the conductive traces and pads in IMD layer 118.

As shown in FIG. 9B, at a next stage of the process, an optical sensor die 100 is placed in the recess (e.g., recess 12R) in each of the plurality of glass substrates. The optical sensor die may be attached (e.g., bonded) by a wire-free connector 154 to a metal pad (e.g., metal pad 124) in the IMD layer 116 on the top surface TR (i.e., on the bottom of the recess). Wire-free connector 154 may be a solder ball.

As shown in FIG. 9C, at a next stage of the process, an encapsulant (molding) material layer 160 is disposed on each of the plurality of glass substrates disposed on carrier 901 and in the spaces between the plurality of glass substrates.

Further, as shown in FIG. 9D, at a next stage of the process in preparation for receiving solder bumps, photoresist patterning and etching may expose conductive pads (e.g., metal pad 126) in IMD layer 118 disposed on bottom surface BG of the glass substrate along a perimeter of recess 12R.

A next stage of processing includes disposing and reflowing solder bumps (e.g., solder balls 152) on the conductive pads (e.g., metal pad 126) in the second RDL layer. FIG. 9E shows an array of solder bumps (e.g., BGA 150) formed on the conductive pads (e.g., pads 126) on bottom surface BG of the glass substrate along a perimeter of recess 12R. The array of solder balls can form the ball grid array of solder bumps forming the external contacts for each individual optical sensor die package.

A next stage of processing further includes, as shown in FIG. 9F, singulating an assembly of the glass substrates disposed on carrier 901 to isolate individual optical sensor packages on carrier 901. The singulation may include sawing through the encapsulant material disposed in the spaces between the plurality of glass substrates disposed on the carrier 901.

Further processing includes, as shown in FIG. 9G, removing, or separating individual the wire-free optical sensor packages (e.g., optical sensor package 300A) from carrier 901.

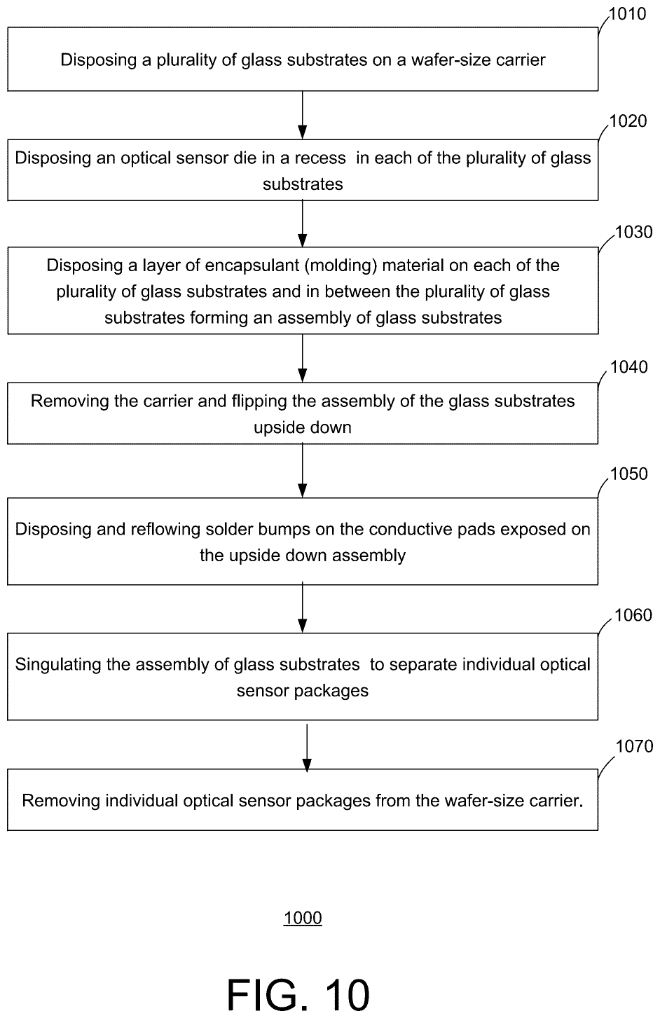

FIG. 10 shows another example method 1000 that involves wafer-level processes and die-level processes for fabricating a wire-free optical sensor package including an optical sensor die disposed in a recess in an inorganic substrate (e.g., a glass substrate). Like in method 600 and method 800, the resulting package may be configured as a ball grid array package with solder balls forming the external electrical contacts or terminals of the package (e.g., wire-free optical sensor package 300B, FIG. 3B).

As shown in FIGS. 3A and 3B, glass substrate 12 (as in FIG. 1A) may be a rectangular piece of glass having a width GW and a thickness GT. A recess 12R (e.g., a rectangular recess) having a width RW and a depth RD may be formed in the glass substrate through the backside (e.g., back surface BG). Width RW may be greater than width DW of die 110. An IMD layer 116 including conductive traces and pads (e.g., metal pad 124) may be disposed on a top surface TR (i.e., on the bottom of the recess). IMD layer 116 may include optically transparent dielectrics and/or metals. An IMD layer 118 may be disposed on a bottom surface BG of the glass substrate along a perimeter of recess 12R. IMD layer 118 includes conductive traces and pads (e.g., metal pad 126). A conductive trace (e.g., metal trace 117) may be disposed on sidewall SR of the recess to electrically connect the conductive traces and pads in IMD layer 116 to the conductive traces and pads in IMD layer 118. Further, as shown in FIG. 3B, an IMD layer 218 may be disposed on top surface TG of the glass substrate. IMD layer 218 may include conductive traces and pads (e.g., metal pad 128). IMD layer 218 may be connected to IMD layer 118 by conductive material filled TGVs. (e.g., TGV 163).

Method 1000 includes disposing a plurality of glass substrates on a wafer-size carrier (1010). The wafer size-carrier may, for example, have a size compatible with that of a semiconductor wafer used in semiconductor device fabrication processes. The wafer-size carrier may, for example, be a wafer made of semiconductor material, a metal, or a ceramic. The glass substrates may be attached to the wafer-size carrier with a temporary adhesive. A pick-and-place technique may be used to individually dispose each of the plurality of glass substrates on the wafer-size carrier.

Method 1000 further includes disposing an optical sensor die in a recess (e.g., recess 12R) in each of the plurality of glass substrates (1020). Disposing the optical sensor die in the recess includes attaching the optical sensor die to the IMD layer 116 including conductive traces and pads (e.g., metal pad 124) on the top surface TR (i.e., on the bottom of the recess). A pick-and-place die attach process may be used to place an individual optical sensor die in the recess in each of the plurality of glass substrates. The optical sensor die may be placed upside down so that the OASA of the die is facing the bottom of the recess. The optical sensor die may be attached (bonded) to the glass wafer by a wire-free connector (e.g., a solder ball). In some other example implementations, the wire-free connector may include a gold bump, a solder micro-bump, or a copper pillar. The wire-free connector may electrically connect the metal pad in IMD layer 116 to device contact pads next to the OASA on the optical sensor die. Further, the wire-free connector may raise the optical sensor die to a height above the surface of IMD layer 116 forming an air cavity between the OASA of the die and the glass wafer.

Next, method 1000 include disposing a layer of encapsulant (molding) material on each of the plurality of glass substrates and in the spaces between the plurality of glass substrates disposed on the wafer-size carrier (1030). Method 1000 may further include removing the carrier and flipping an assembly of the glass substrates upside down (1040). This may expose conductive pads (e.g., metal pad 128) in IMD layer 218 disposed on a bottom surface BG of the glass substrate along a perimeter of recess 12R. In some implementations, photoresist patterning and etching may be used expose conductive pads in an IMD layer disposed on bottom surface of the glass substrate along a perimeter of the recess.

Method 1000 further includes disposing and reflowing solder bumps on the conductive pads on the upside down assembly (1050). The solder bumps formed on the conductive pads exposed on the bottom surface BG of the glass substrate may constitute a ball grid array (BGA) of solder bumps. Method 1000 further includes singulating the assembly of glass substrates to isolate and separate individual optical sensor packages (1060). The singulation may include sawing through the encapsulant material disposed in the spaces between the plurality of glass substrates disposed on the wafer-size carrier.

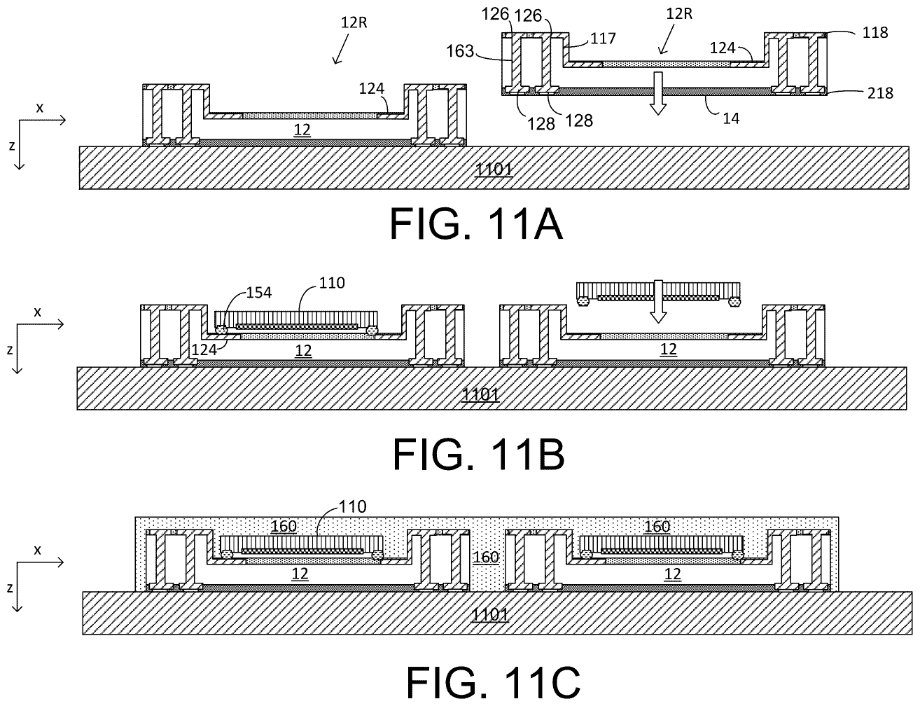

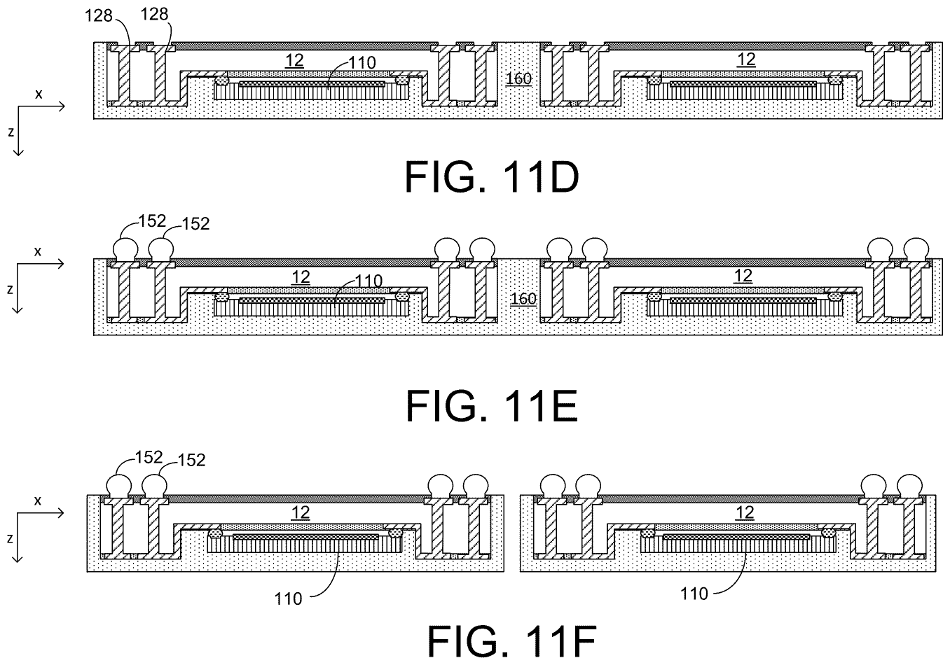

FIGS. 11A through 11F schematically illustrate cross-sectional views of glass substrates and optical sensor dies being processed through multiple process steps for making a wire-free optical sensor package (e.g., according to the method of FIG. 10).

FIG. 11A shows, for example, an initial stage of the process, in which a plurality of glass substrates (e.g., glass substrate 12) are disposed on and affixed to a carrier 1101 using a temporary adhesive 14. Each of the glass substrates (e.g., substrate 12) may include a recess (e.g., recess 12R). Elements of a signal redistribution layer for an optical sensor die to be included in the optical sensor package may be disposed on surfaces of the glass substrate and the recess. For example, an IMD layer 116 including conductive traces and pads (e.g., metal pad 124) may be disposed on a top surface TR (i.e., on the bottom of the recess). An IMD layer 118 may be disposed on a bottom surface BG of the glass substrate along a perimeter of recess 12R. IMD layer 118 includes conductive traces and pads (e.g., metal pad 126). A conductive trace (e.g., metal trace 117) may be disposed on sidewall SR (FIG. 9A) of the recess to electrically connect the conductive traces and pads in IMD layer 116 to the conductive traces and pads in IMD layer 118. Further, a plurality of through-glass vias (e.g., TGV 163) filled or lined with conductive material may connect metal pad 124 on the top surface of glass substrate 12A to metal pad 126 on the bottom surface of glass substrate 12.

As shown in FIG. 11B, at a next stage of the process, an optical sensor die 110 is placed in the recess (e.g., recess 12R) in each of the plurality of glass substrates. The optical sensor die may be attached (e.g., bonded) by a wire-free connector 154 to a metal pad (e.g., metal pad 124) in the IMD layer 116 on the top surface TR (i.e., on the bottom of the recess).

As shown in FIG. 11C, at a next stage of the process, an encapsulant (molding) material layer 160 is disposed on each of the plurality of glass substrates disposed on carrier 1101 and in the spaces between the plurality of glass substrates. The molding material joins the glass substrates disposed on carrier 1101 to form a rigid assembly of substrates.

At a next stage of the process, the assembly of glass substrates is removed from carrier 1101 and flipped upside down (not shown).

Further, at this next stage of the process, in preparation for receiving solder bumps, as shown in FIG. 11D, photoresist patterning and etching may expose conductive pads (e.g., metal pad 128) in IMD layer 218 disposed on bottom surface BG of the glass substrate along a perimeter of recess 12R.

A next stage of processing includes disposing and reflowing solder bumps (e.g., solder balls 152) on the conductive pads (e.g., metal pad 128) disposed on bottom surface BG of the glass substrate. FIG. 11E shows an array of solder balls 152 disposed on bottom surface BG of the glass substrate. The solder balls 152 can form the ball grid array of solder bumps forming the external contacts for each individual optical sensor die package.

A next stage of processing further includes, as shown in FIG. 11F, singulating an assembly of the glass substrates to isolate and separate individual optical sensor packages (e.g., wire-free optical sensor package 300B) from each other. The singulation may include sawing through the encapsulant material disposed in the spaces between the plurality of glass substrates disposed on carrier 1101.

A method for fabricating an optical sensor package includes disposing a first redistribution layer on a first side of an inorganic wafer, attaching at least one optical sensor die on to the first redistribution layer on the first side of the inorganic wafer, and disposing a layer of encapsulant material on the first side of the inorganic wafer to encapsulate the at least one optical sensor die. The method further includes etching vias through the layer of encapsulant material, forming a second redistribution layer on the layer of encapsulant material and disposing a passivating dielectric layer on the second redistribution layer. The method further includes opening bond pads in the second redistribution layer through the passivating dielectric layer, disposing and reflowing solder bumps on the bond pads in the second redistribution layer; and singulating the inorganic wafer to separate individual optical sensor packages.

Attaching the at least one optical sensor die on to the first redistribution layer includes attaching the at least one optical sensor die on to the first redistribution layer by a wire-free connector. The wire-free connector may be one of a solder ball, a gold bump, a solder micro-bump, or a copper pillar.

Disposing and reflowing the solder bumps on the second redistribution layer includes forming a ball grid array for external electrical contacts or terminals of a package including the at least one optical sensor die.

A method for fabricating an optical sensor package includes disposing a plurality of glass substrates on a wafer-size carrier, disposing an optical sensor die in a recess in each of the plurality of glass substrates, and disposing a layer of molding material on each of the plurality of glass substrates and in spaces between the plurality of glass substrates. The method further includes patterning and etching a top layer of the layer of molding material to expose conductive pads, disposing and reflowing solder bumps on the conductive pads. The method further includes singulating an assembly of glass substrates disposed on the wafer-size carrier to separate individual optical sensor packages, and removing individual optical sensor packages from the wafer-size carrier.

Disposing an optical sensor die in a recess includes attaching the optical sensor die to an inter-metal dielectric layer disposed on a surface of the recess using a wire-free connector. The wire-free connector may be one of a solder ball, a gold bump, a solder micro-bump, or a copper pillar.

Disposing the layer of molding material on each of the plurality of glass substrates includes disposing the layer of molding material on conductive pads in an inter-metal dielectric layer disposed on a bottom surface of the glass substrate along a perimeter of the recess.

Disposing and reflowing solder bumps on the conductive pads exposed by the etching includes forming a ball grid array of solder bumps as a set of external contacts for each individual optical sensor die package.

A Method for fabricating an optical sensor package includes disposing a plurality of glass substrates on a carrier, disposing an optical sensor die in a recess in each of the plurality of glass substrates, disposing a layer of molding material on each of the plurality of glass substrates and in between the plurality of glass substrates forming an assembly of glass substrates, and removing the carrier and flipping the assembly of the glass substrates upside down exposing conductive pads on an upper surface of the upside down assembly of the glass substrates. The method further includes disposing and reflowing solder bumps on the conductive pads on the upside down assembly of the glass substrates, singulating the assembly of glass substrates disposed on the carrier to separate individual optical sensor packages, and removing individual optical sensor packages from the carrier.

Disposing an optical sensor die in the recess includes attaching the optical sensor die to an inter-metal dielectric layer disposed on a surface of the recess using a wire-free connector. The wire-free connector can be one of a solder ball, a gold bump, a solder micro-bump, or a copper pillar.

Disposing and reflowing solder bumps on the conductive pads exposed on the upside down assembly of the glass substrates includes forming a ball grid array of solder bumps as external contacts for each individual optical sensor die package.

The method further includes singulating through the assembly of the glass substrates to separate individual optical sensor packages.

An example wire-free optical sensor package may include an optical sensor die that is coupled to a layer of ASIC circuitry or to an ASIC die. The optical devices of an optical sensor may be fabricated in an optical sensor die and coupled to circuitry (e.g., application specific integrated circuits (ASIC) including a driver circuit, A/D converter, etc.). The ASIC circuitry may be fabricated on a same semiconductor die as the devices for detecting light intensity, or on a separate semiconductor die coupled to the optical sensor die. ASIC circuitry fabricated on the same semiconductor die as the optical sensor die may in some instances be also referred to as the “ASIC die” herein.

In example implementations the optical sensor die may be stacked above the ASIC die. The dies may be physically joined to each other with hybrid bonds (copper-copper bonds and oxide-oxide bonds) formed in a silicon dioxide matrix layer disposed between the ASIC die and the Sensor die. The dies may be physically joined to each other by bonding conductive traces or pads of redistribution layers on opposing surfaces of the dies using conductive bonding material (e.g., solder bumps, micro-bumps, copper pillars) disposed on the opposing surfaces of the dies.

In example implementations, the stack of the optical sensor die and the ASIC die may be disposed on a top surface of a glass substrate. In some implementations, metallization on the ASIC die and on the glass substrate may be connected by hybrid bonds (copper-copper bonds and oxide-oxide bonds) formed in a silicon dioxide matrix layer disposed between the ASIC die and the glass substrate. In some implementations, the connection may be made, for example, by direct copper pad-to-copper pad bonds, or copper pillar-to-copper pillar connections. In some implementations, tin/silver micro-bumps may be used to connect the metallization on the ASIC die and on the glass substrate. Conductive material filled or lined TGVs may extend through the glass substrate. External package connections (solder balls) may be disposed on a bottom surface of the glass substrate without using wire bonds to the optical sensor die.

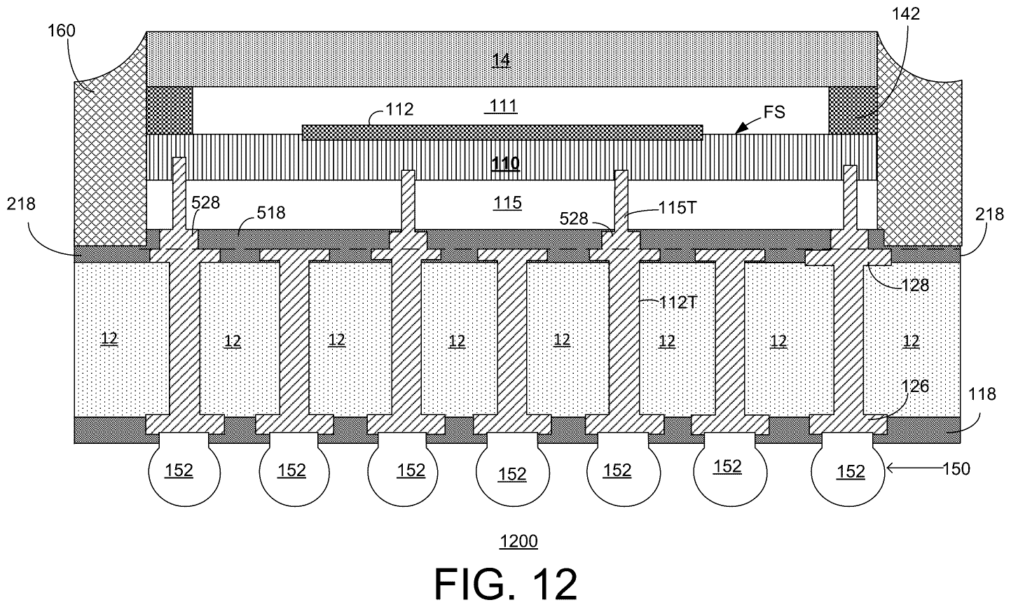

FIG. 12 shows an example wire-free optical sensor package 1200 that includes an optical sensor die 110 coupled to, and arranged in a stack above an ASIC die 115. The ASIC die may include at least one backside through-semiconductor via (BTSV) (e.g., TSV 115T) for electrical connections to the optical sensor die. TSV 115T may be lined with a passivating dielectric (e.g., silicon dioxide) (not shown). The ASIC die (or the stack of the optical sensor die and the ASIC die/circuitry) may be connected to a bottom surface of the glass substrate by through-glass conductive vias (e.g., TGV 112T) extending through the glass substrate. In the example shown in FIG. 12, conductive material filled or lined TSV 115T may connect optical sensor die 112 to conductive pad 128 in IMD layer 218 disposed on a top surface of the glass substrate.

Further, conductive material filled or lined through-glass vias (e.g., TGV 112T) in the glass substrate may connect conductive pads 128 in IMD layer 218 disposed on the top surface of the glass substrate to conductive pads 126 in IMD layer 118 disposed on the bottom surface of the glass substrate. Solder balls 152 disposed on the conductive pads 126 may form the input/output terminals of the package, for example, as a ball grid array (BGA) 150 on the back surface of the glass substrate.

In example implementations, the glass substrate may have a width that is larger than a width of the optical sensor die/ASIC stack in the package and can connect the enclosed optical sensor die/ASIC die stack to a large number of input/outputs of the package through the conductive vias present in the glass substrate.

The optical sensor package is further encapsulated in a molding material compound (molding material 160) to protect the enclosed devices and structures from the environment (e.g., from humidity or moisture in the environment), and for mechanical (i.e., structural) sturdiness of the package (e.g., an iBGA package).

As shown in FIG. 12, the optical sensor package may include a transparent window, cover, or lid (e.g., a glass cover 14) placed over the stack of the optical sensor die and the ASIC die. Glass cover 14 may be attached to optical sensor die 110, for example, by a bead of adhesive material (e.g., dam 142) disposed on a front surface (FS) of the optical sensor die 110 along the edges on the die. Although it is not explicitly shown in the figure, dam 142 extends all the way around the edge of the die. Glass cover 14 may be supported above the optical sensor die by dam 142 so that there is an air gap (e.g., air gap 111) between the glass cover and the front surface FS of optical sensor die 110.

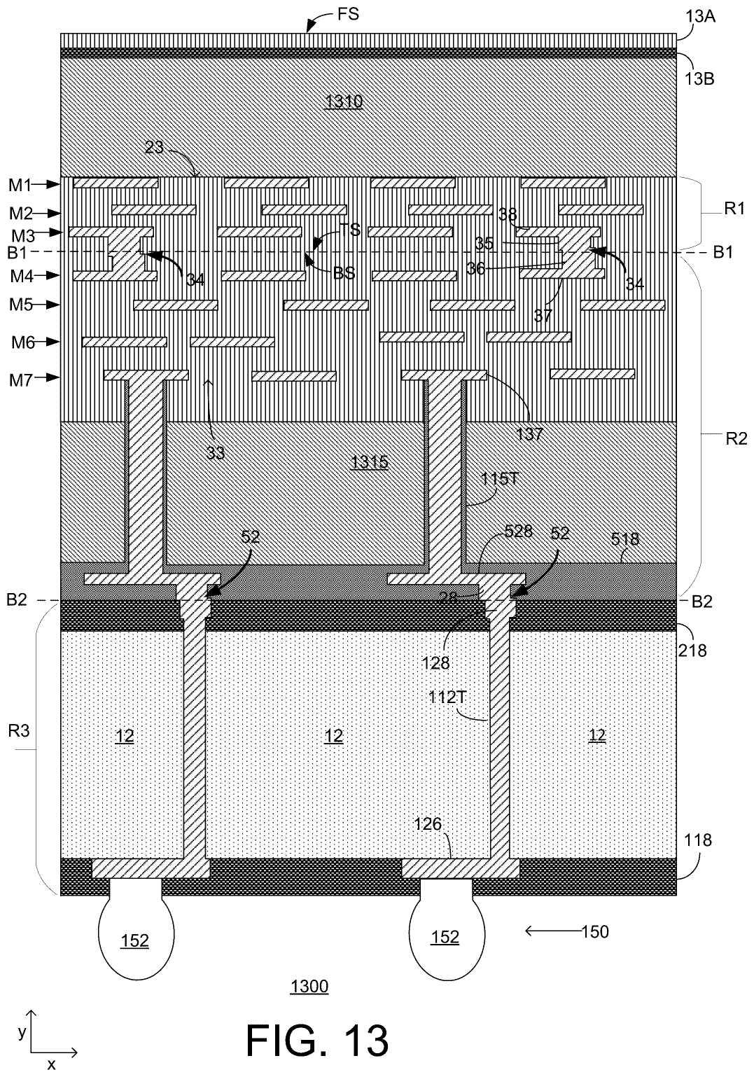

FIG. 13 shows an exploded cross-sectional view of a stack of an optical sensor die and ASIC die that may be disposed on a glass substrate in an optical sensor package (e.g., package 1300). FIG. 13 illustrates the metallization levels and the hybrid bonding structure coupling an optical sensor die (e.g., optical sensor die 1310 made of silicon), an ASIC die (e.g., ASIC die 1315 made of silicon) and a glass substrate (e.g., glass substrate 12) to a solder ball grid array (e.g., array 150) that forms the external input/output terminals of the package. For visual clarity (in consideration of page size limitations), FIG. 13 does not show the OASA and a glass cover that may be disposed on front surface (FS) of the optical sensor die 1310 in package 1300. In the view shown in FIG. 13, front surface FS of optical sensor die 1310 may be covered by passivation layers 13A and 13B. Passivating layer 13B may, for example, be a backside illuminated (BSI) hik dielectric layer (including, e.g., Al2O3, HfO2 and Ta2O5). Passivating layer 13A may be a silicon oxide layer.

As shown in FIG. 13, optical sensor die 1310 has an associated redistribution layer (e.g., RDL R1), which includes, for example, traces and conductive pads in metal levels M1, M2 and M3 disposed in a dielectric material (e.g., silicon oxide layer 23). Metal level M3 may, for example, include a conductive pad 38 (e.g., a copper pad) that is connected to a copper pad 35 that is exposed and planarized at a bottom surface (BS) of silicon oxide layer 23.

Further, ASIC die 1315 has an associated redistribution layer (e.g., RDL R2), which includes, for example, traces and conductive pads in metal levels M4, M5, M6 and M7 disposed in a dielectric material layer (e.g., silicon oxide layer 33). Metal level M4 may, for example, include a conductive pad 37 (e.g., a copper pad) that is connected to a copper pad 36 that is exposed and planarized at a top surface (TS) of silicon oxide layer 33.

In package 1300, optical sensor die 1310 and AISC die 1315 are joined together by a hybrid bond extending along bond line B1. The hybrid bond involves oxide-oxide bonding of oxide layer 23 of RDL R1 and oxide layer 33 of RDL R2 along bond line B1. The hybrid bond also involves a metal-metal bond 34 formed between the planarized surface of copper pad 35 in RDL R1 and planarized surface of copper pad 36 of RDL R2 along bond line B1.

Further, RDL R2 associated with ASIC die 1315 includes IMD layer 518, on a bottom surface of ASIC die 1315. IMD layer 518 may include a conductive pad 528. Conductive pad 528 is connected to conductive pad 137 in metal level M7 by a conductive material filled or lined through-silicon via (e.g., TSV 115T) extending through the thickness of ASIC die 1315.

Further, RDL 3 associated with glass substrate 12 includes IMD layer 218 disposed on a top surface of glass substrate 12 and an IMD layer 118 disposed on a bottom surface glass substrate 12. IMD layer 218 may include a conductive pad 128 (e.g., a copper pad) and IMD layer 118 may include a conductive pad 126. Conductive pads 128 and 126 are connected by conductive material filled or lined through-glass vias (e.g., TGV 112T) extending through the glass substrate.

In package 1300, AISC die 1315 and glass substrate 12 are mechanically and electrically joined together by a hybrid bond extending along bond line B2. The hybrid bond involves, for example, oxide-oxide bonding of IMD layer 518 of RDL R2 and IMD 218 of RDL layer R3 along bond line B2. The hybrid bond also involve a metal-metal bond 52 between the planarized surface of copper pad 28 in RDL R2 and the planarized surface of copper pad 128 of RDL R3 along bond line B1.

The hybrid bonds described in the foregoing, electrically connect optical sensor die 1310 and ASIC die 1315 to the external terminals of the package represented by solder balls 152 disposed on the bottom side of glass substrate 12.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms such as over, above, upper, under, beneath, below, lower, and so forth, are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

What is claimed is:

1. A package, comprising:
an inorganic substrate;
a first inter-metal dielectric layer disposed on a first surface of the inorganic substrate;
an optical sensor die attached to and electrically connected to a pad in the first inter-metal dielectric layer by a connector;
a molding material layer disposed on the first inter-metal dielectric layer encapsulating the optical sensor die;
a second inter-metal dielectric layer disposed on the molding material layer; and
an opening extending through the molding material layer between the first inter-metal dielectric layer and the second inter-metal dielectric layer, wherein the opening is filled or lined with conductive material electrically connecting the first inter-metal dielectric layer and the second inter-metal dielectric layer.

2. The package of claim 1, wherein the connector is one of a solder ball, a gold bump, a solder micro-bump, or a copper pillar.

3. The package of claim 1, wherein the opening is filled with solder and connects to a solder ball disposed on the second inter-metal dielectric layer.

4. The package of claim 1, wherein the opening is a through-mold via filled or lined with copper.

5. The package of claim 1, further comprising:
at least a solder ball coupled to a metal pad in the second inter-metal dielectric layer.

6. The package of claim 1, wherein an array of solder balls coupled to the second inter-metal dielectric layer form external terminals of the package.

7. A package, comprising:
an inorganic substrate;
a first inter-metal dielectric layer disposed on a first surface of the inorganic substrate;
an optical sensor die attached and electrically connected to a pad in the first inter-metal dielectric layer by a connector;
a molding material layer disposed on the first inter-metal dielectric layer, the molding material layer encapsulating the optical sensor die;
a second inter-metal dielectric layer disposed on a second surface of the inorganic substrate opposite the first surface; and
a through-glass via connecting the first inter-metal dielectric layer and the second inter-metal dielectric layer.

8. The package of claim 7, wherein the connector one of a solder ball, a gold bump, a solder micro-bump, or a copper pillar.

9. The package of claim 7, wherein copper is disposed in the through-glass via.

10. The package of claim 7, wherein an array of solder balls coupled to the second inter-metal dielectric layer form external terminals of the package.

11. The package of claim 7, wherein the first inter-metal dielectric layer includes portions that have a black color with high absorption and low reflection of visible and infrared light.

12. A package, comprising:
an inorganic substrate, the inorganic substrate being a piece of glass with a recess therein extending through a back surface of the piece of glass;
a first inter-metal dielectric layer disposed on a first surface of the recess;
an optical sensor die disposed in the recess, the optical sensor die being attached and electrically connected to a pad in the first inter-metal dielectric layer by a connector;
a molding material layer disposed in the recess, the molding material layer encapsulating the optical sensor die;
a second inter-metal dielectric layer disposed on the back surface of the inorganic substrate along a perimeter of the recess; and
a metal trace disposed on a side of the recess connecting the first inter-metal dielectric layer and the second inter-metal dielectric layer.

13. The package of claim 12, wherein the connector is one of a solder ball, a gold bump, a solder micro-bump, or a copper pillar.

14. The package of claim 12, wherein an array of solder balls coupled to the second inter-metal dielectric layer form external terminals of the package.

15. A package, comprising:
an inorganic substrate, the inorganic substrate being a piece of glass with a recess therein extending through a back surface of the piece of glass;
a first inter-metal dielectric layer disposed on a first surface of the recess;
an optical sensor die disposed in the recess, the optical sensor die being attached and electrically connected to a pad in the first inter-metal dielectric layer by a connector;
a molding material layer disposed in the recess, the molding material layer encapsulating the optical sensor die;
a second inter-metal dielectric layer disposed on the back surface of the piece of glass along a perimeter of the recess;
a metal trace disposed on a side of the recess connecting the first inter-metal dielectric layer and the second inter-metal dielectric layer;
a third inter-metal dielectric layer disposed on a top surface of the piece of glass; and
a conductive material filled or lined through-glass via connecting the first inter-metal dielectric layer and the second inter-metal dielectric layer.

16. The package of claim 15, wherein an array of solder balls coupled to the third inter-metal dielectric layer form external terminals of the package.

17. The package of claim 15, wherein an array of solder balls coupled to the second inter-metal dielectric layer form external terminals of the package.

18. The package of claim 15, further comprising: at least one through-glass via connecting the first inter-metal dielectric layer and the third inter-metal dielectric layer.

19. The package of claim 15, wherein the piece of glass includes a hole, the hole venting an air cavity formed above the optical sensor die to an ambience of the package.

20. The package of claim 15, wherein the first inter-metal dielectric layer and/or the second inter-metal dielectric layer includes portions that have a black color with high absorption and low reflection of visible and infrared light.

21. A package, comprising:
an optical sensor die;
an application specific integrated circuit die; and
a glass substrate, the optical sensor die arranged in a stack above the application specific integrated circuit die, the stack being coupled to the glass substrate.

22. The package of claim 21, wherein an array of solder balls coupled to the glass substrate form external terminals of the package.

23. The package of claim 21 further comprising:
a glass cover disposed above a front surface of the optical sensor die. the glass cover enclosing an air cavity above the front surface of the optical sensor die.

24. The package of claim 21, wherein the optical sensor die is attached to the application specific integrated circuit die along a first bond line by a first hybrid bond including an oxide-oxide bond and a metal-metal bond, and the application specific integrated circuit die is attached to the glass substrate along a second bond line by a second hybrid bond including an oxide-oxide bond and a metal-metal bond.

25. The package of claim 21, wherein a conductive material disposed in a through-substrate via in the application specific integrated circuit die provides electrical connection to the optical sensor die in the stack.

26. The package of claim 21, wherein a conductive material disposed in a through-glass via in the glass substrate provides electrical connection to the optical sensor die in the stack.
